(19) United States
(12) Patent Application Publication
(10) Pub. No.: US 2021/0264369 A1
(43) Pub. Date: Aug. 26, 2021

(54) Generating and Presenting Scripts Related to Different Sections of Construction Sites

(71) Applicant: Ron Zass, Kiryat Tivon (IL)

(72) Inventor: Ron Zass, Kiryat Tivon (IL)

(21) Appl. No.: 17/315,438

(22) Filed: May 10, 2021

Related U.S. Application Data
(60) Provisional application No. 63/036,784, filed on Jun. 9, 2020.

(51) Int. Cl. G06Q 10/10; G06T 7/00; G06K 9/00; G06T 11/60; G06T 13/80; G06T 13/40; G06F 3/16; G06Q 50/08; G06Q 10/06

(52) U.S. Cl. CPC G06Q 10/103; G06T 7/0002; G06K 9/00624; G06T 11/60; G06T 13/80; G06Q 10/0875; G06F 3/167; G06Q 50/08; G06Q 10/06312; G06Q 10/06313; G06Q 10/0635; G06T 13/40

(57) ABSTRACT

Systems, methods and non-transitory computer readable media for generating and presenting scripts related to different sections of construction sites are provided. First and second information are received, the first information corresponds to a first section of a construction site and the second information corresponds to a second section of the construction site. A script based on the first and second information is generated, the generated script includes a first portion associated with the first section of the construction site and a second portion associated with the second section of the construction site. The generated script is presented, the presentation of the generated script includes a presentation of the first portion of the generated script in conjunction with a visual presentation of the first image data and a presentation of the second portion of the generated script in conjunction with a visual presentation of the second image data.

### CROSS REFERENCES TO RELATED APPLICATIONS

This application claims the benefit of priority of U.S. Provisional Patent Application No. 63/036,784, filed on Jun. 9, 2020.

The entire content of the above-identified application is herein incorporated by reference.

### BACKGROUND

### Technological Field

The disclosed embodiments generally relate to systems and methods for processing images to generate and visually present scripts. More particularly, the disclosed embodiments relate to systems and methods for processing construction site images to generate and visually present scripts related to construction sites.

### Background Information

Image sensors are now part of numerous devices, from security systems to mobile phones, and the availability of images and videos produced by those devices is increasing.

The construction industry deals with building of new structures, additions and modifications to existing structures, maintenance of existing structures, repair of existing structures, improvements of existing structures, and so forth. While construction is widespread, the construction process still needs improvements. Manual monitoring, analysis, inspection, and management of the construction process prove to be difficult, expensive, and inefficient. As a result, many construction projects suffer from cost and schedule overruns, and in many times the quality of the constructed structures is lacking.

### SUMMARY

In some embodiments, systems comprising at least one processor are provided. In some examples, the systems may further comprise at least one of an image sensor, a display device, a communication device, a memory unit, and so forth.

In some embodiments, systems, methods and non-transitory computer readable media for providing information on construction sites based on construction site images and/or construction plans are provided.

In some embodiments, systems, methods and non-transitory computer readable media for generating and presenting scripts related to different sections of construction sites are provided. First information and second information may be received, the first information may be based on an analysis of a first image data captured from a first section of a construction site and the second information may be based on an analysis of a second image data captured from a second section of the construction site, the second section of the construction site may differ from the first section of the construction site. A script based on the first information and the second information may be generated, the generated script may include at least a first portion associated with the first section of the construction site and a second portion associated with the second section of the construction site. A presentation of the generated script may be caused, the presentation of the generated script may include a presentation of the first portion of the generated script in conjunction with a visual presentation of at least part of the first image data and a presentation of the second portion of the generated script in conjunction with a visual presentation of at least part of the second image data. In one example, the first information may be information on a status of the first section of the construction site, and the second information may be information on a status of the second section of the construction site. In one example, the first image data and the second image data may be received, the first image data may be analyzed to determine the first information, and the second image data may be analyzed to determine the second information. For example, a convolution of at least a portion of the first image data may be calculated, and the calculated convolution may be used to determine the first information. In another example, a convolution of at least a portion of the second image data may be calculated, and the calculated convolution may be used to determine the second information. In one example, the presentation of the first portion of the generated script and the presentation of the second portion of the generated script may be audible. In one example, the presentation of the first portion of the generated script may include a presentation of the first portion of the generated script in a textual form in conjunction with the visual presentation of the at least part of the first image data, and the presentation of the second portion of the generated script may include a presentation of the second portion of the generated script in textual form in conjunction with the visual presentation of the at least part of the second image data. In one example, the generated script may be used to generate a visual representation of a synthetic character presenting the generated script, the presentation of the generated script by the synthetic character may include a presentation of the first portion of the generated script by the synthetic character in conjunction with the visual presentation of the at least part of the first image data and a presentation of the second portion of the generated script by the synthetic character in conjunction with the visual presentation of the at least part of the second image data. In one example, the first portion of the generated script may be indicative of a delay at the first section of the construction site, and the second portion of the generated script may be indicative of a delay at the second section of the construction site. In one example, the first portion of the generated script may be indicative of a completion of work at the first section of the construction site, and the second portion of the generated script may be indicative of a completion of work at the second section of the construction site. In one example, the first portion of the generated script may be indicative of a construction error at the first section of the construction site, and the second portion of the generated script may be indicative of a construction error at the second section of the construction site. In one example, the first portion of the generated script may be indicative of a quality issue at the first section of the construction site, and the second portion of the generated script may be indicative of a quality issue at the second section of the construction site. In one example, the first portion of the generated script may be indicative of a safety issue at the first section of the construction site, and wherein the second portion of the generated script may be indicative of a safety issue at the second section of the construction site. In one example, the first portion of the generated script may be indicative of a usage of materials at the first section of the construction site, and the second portion of the generated script may be indicative of a usage of materials at the second section of the construction site. In one example, the first portion of the generated script may be indicative of a material used at the first section of the construction site, and the second portion of the generated script may be indicative of a material used at the second section of the construction site. In one example, the first portion of the generated script may be indicative of a first prospective construction work at the first section of the construction site, and wherein the second portion of the generated script may be indicative of a second prospective construction work at the second section of the construction site. In one example, the first portion of the generated script may be indicative of a readiness for a prospective construction work at the first section of the construction site, and the second portion of the generated script may be indicative of a unreadiness for the prospective construction work at the second section of the construction site.

In some embodiments, systems, methods and non-transitory computer readable media for generating and presenting scripts related to different time periods in construction sites are provided. First information related to a status of a construction site during a first time period and second information related to a status of the construction site during a second time period may be received. The second time period may differ from the first time period. The first information may be based on an analysis of a first image data captured from the construction site during the first time period and the second information may be based on an analysis of a second image data captured from the construction site during the second time period. A script based on the first information and the second information may be generated. The generated script may include at least a first portion associated with the status of the construction site during the first time period and a second portion associated with the status of the construction site during the second time period. A presentation of the generated script, the presentation of the generated script may include a presentation of the first portion of the generated script in conjunction with a visual presentation of at least part of the first image data and a presentation of the second portion of the generated script in conjunction with a visual presentation of at least part of the second image data. In some examples, the first image data and the second image data may be received, the first image data may be analyzed to determine the first information, and the second image data may be analyzed to determine the second information. In one example, a convolution of at least a portion of the first image data may be calculated, and the calculated convolution may be used to determine the first information. In one example, a convolution of at least a portion of the second image data may be analyzed, and the calculated convolution may be used to determine the second information. In some examples, there may be no overlap between the first time period and the second time period, there may be some overlap between the first time period and the second time period, and so forth. In some examples, the presentation of the first portion of the generated script and the presentation of the second portion of the generated script may be audible. In some examples, the presentation of the first portion of the generated script may include a presentation of the first portion of the generated script in a textual form in conjunction with the visual presentation of the at least part of the first image data, and the presentation of the second portion of the generated script may include a presentation of the second portion of the generated script in textual form in conjunction with the visual presentation of the at least part of the second image data. In one example, the generated script may be related to a construction error visible in the first image data and fixed before the second time period, the first portion of the generated script may relate to the construction error and the second portion of the generated script may relate to the fix of the construction error. In one example, the generated script may be related to a usage of materials at the construction site between the first time period and the second time period. In one example, the generated script may be related to a material used at the construction site between the first time period and the second time period. In one example, the generated script may be related to a work performed at the construction site between the first time period and the second time period. In one example, the generated script may be related to an issue resolved at the construction site between the first time period and the second time period (such as a safety issue, a quality issue, a scheduling issue, and so forth). In one example, the generated script may be related to an issue arising at the construction site between the first time period and the second time period (such as a safety issue, a quality issue, a scheduling issue, and so forth). In one example, the generated script may be related to a delay arising at the construction site between the first time period and the second time period. In some examples, the generated script may be used to generate a visual representation of a synthetic character presenting the generated script. The presentation of the generated script by the synthetic character may include a presentation of the first portion of the generated script by the synthetic character in conjunction with the visual presentation of the at least part of the first image data and a presentation of the second portion of the generated script by the synthetic character in conjunction with the visual presentation of the at least part of the second image data.

In some embodiments, systems, methods and non-transitory computer readable media for generating and presenting scripts related to different portions of construction plans are provided. In some examples, first information and second information may be received, the first information may be based on an analysis of a first part of a construction plan and the second information may be based on an analysis of a second part of the construction plan, the second part of the construction plan differs from the first part of the construction plan. In some examples, a script may be generated based on the first information and the second information, the generated script includes at least a first portion associated with the first part of the construction plan and a second portion associated with the second part of the construction plan. A presentation of the generated script may be caused. The presentation of the generated script may include a presentation of the first portion of the generated script in conjunction with a visual presentation of the first part of the construction plan and a presentation of the second portion of the generated script in conjunction with a visual presentation of the second part of the construction plan. In some examples, the first part of the construction plan may correspond to a first section of a construction site and the second part of the construction plan may correspond to a second section of the construction site, the second section of the construction site may differ from the first section of the construction site. For example, the first information may be or include information on a status of the first section of the construction site and the second information may be or include information on a status of the second section of the construction site. In another example, the first information may be further based on an analysis of first image data captured from the first section of the construction site and the second information may be further based on an analysis of second image data captured from the first section of the construction site. For example, the first image data may be received, and the first image data may be analyzed to generate the first information. For example, the second image data may be analyzed, and the second image data may be analyzed to generate the second information. In one example, the first portion of the generated script may be related to a delay at the first section of the construction site, and the second portion of the generated script may be related to a delay at the second section of the construction site. In one example, the first portion of the generated script may be related to a completion of work at the first section of the construction site, and the second portion of the generated script may be related to a completion of work at the second section of the construction site. In one example, the first portion of the generated script may be related to a construction error at the first section of the construction site, and the second portion of the generated script may be related to a construction error at the second section of the construction site. In one example, the first portion of the generated script may be related to a quality issue at the first section of the construction site, and the second portion of the generated script may be related to a quality issue at the second section of the construction site. In one example, the first portion of the generated script may be related to a safety issue at the first section of the construction site, and the second portion of the generated script may be related to a safety issue at the second section of the construction site. In one example, the first portion of the generated script may be related to a usage of materials at the first section of the construction site, and the second portion of the generated script may be related to a usage of materials at the second section of the construction site. In one example, the first portion of the generated script may be related to a material used at the first section of the construction site, and the second portion of the generated script may be related to a material used at the second section of the construction site. In one example, the first portion of the generated script may be related to a prospective construction work at the first section of the construction site, and the second portion of the generated script may be related to a prospective construction work at the second section of the construction site. In one example, the first portion of the generated script may be related to a readiness for a prospective construction work at the first section of the construction site, and the second portion of the generated script may be related to an unreadiness for the prospective construction work at the second section of the construction site. In some examples, the presentation of the first portion of the generated script and the presentation of the second portion of the generated script are audible. In some examples, the presentation of the first portion of the generated script may include a presentation of the first portion of the generated script in a textual form in conjunction with the visual presentation of the first part of the construction plan, and the presentation of the second portion of the generated script may include a presentation of the second portion of the generated script in textual form in conjunction with the visual presentation of the second part of the construction plan. In some examples, the generated script may be used to generate a visual representation of a synthetic character presenting the generated script. The presentation of the generated script by the synthetic character may include a presentation of the first portion of the generated script by the synthetic character in conjunction with the visual presentation of the first part of the construction plan and a presentation of the second portion of the generated script by the synthetic character in conjunction with the visual presentation of the second part of the construction plan.

Consistent with other disclosed embodiments, non-transitory computer-readable storage media may store data and/or computer implementable instructions for carrying out any of the methods described herein.

The foregoing general description and the following detailed description are exemplary and explanatory only and are not restrictive of the claims.

### BRIEF DESCRIPTION OF THE DRAWINGS

FIGS. 1A and 1B are block diagrams illustrating some possible implementations of a communicating system.

FIGS. 2A and 2B are block diagrams illustrating some possible implementations of an apparatus.

FIG. 3 is a block diagram illustrating a possible implementation of a server.

FIG. 4A and 4B are block diagrams illustrating some possible implementations of a cloud platform.

FIG. 5 is a block diagram illustrating a possible implementation of a computational node.

FIG. 6 illustrates an exemplary embodiment of a memory storing a plurality of modules.

FIGS. 7A, 7B and 7C are schematic illustrations of example images captured from construction sites and consistent with an embodiment of the present disclosure.

FIG. 7D is a schematic illustration of an example construction plan.

FIGS. 8A and 8B illustrate example methods for generating and presenting scripts related to different sections of construction sites.

FIGS. 9A and 9B illustrate example methods for generating and presenting scripts related to different time periods in construction sites.

FIGS. 10A and 10B illustrate example methods for generating and presenting scripts related to different portions of construction plans.

### DESCRIPTION

Unless specifically stated otherwise, as apparent from the following discussions, it is appreciated that throughout the specification discussions utilizing terms such as “processing”, “calculating”, “computing”, “determining”, “generating”, “setting”, “configuring”, “selecting”, “defining”, “applying”, “obtaining”, “monitoring”, “providing”, “identifying”, “segmenting”, “classifying”, “analyzing”, “associating”, “extracting”, “storing”, “receiving”, “transmitting”, or the like, include action and/or processes of a computer that manipulate and/or transform data into other data, said data represented as physical quantities, for example such as electronic quantities, and/or said data representing the physical objects. The terms “computer”, “processor”, “controller”, “processing unit”, “computing unit”, and “ processing module” should be expansively construed to cover any kind of electronic device, component or unit with data processing capabilities, including, by way of non-limiting example, a personal computer, a wearable computer, a tablet, a smartphone, a server, a computing system, a cloud computing platform, a communication device, a processor, such as, a digital signal processor (DSP), an image signal processor (ISR), a microcontroller, a field programmable gate array (FPGA), an application specific integrated circuit (ASIC), a central processing unit (CPA), a graphics processing unit (GPU), a visual processing unit (VPU), and so on), possibly with embedded memory, a single core processor, a multi core processor, a core within a processor, any other electronic computing device, or any combination of the above.

The operations in accordance with the teachings herein may be performed by a computer specially constructed or programmed to perform the described functions.

As used herein, the phrase “for example,” “such as”, “for instance” and variants thereof describe non-limiting embodiments of the presently disclosed subject matter. Reference in the specification to “one case”, “some cases”, “other cases” or variants thereof means that a particular feature, structure or characteristic described in connection with the embodiment(s) may be included in at least one embodiment of the presently disclosed subject matter. Thus the appearance of the phrase “one case”, “some cases”, “other cases” or variants thereof does not necessarily refer to the same embodiment(s). As used herein, the term “and/or” includes any and all combinations of one or more of the associated listed items.

It is appreciated that certain features of the presently disclosed subject matter, which are, for clarity, described in the context of separate embodiments, may also be provided in combination in a single embodiment. Conversely, various features of the presently disclosed subject matter, which are, for brevity, described in the context of a single embodiment, may also be provided separately or in any suitable sub-combination.

The term “image sensor” is recognized by those skilled in the art and refers to any device configured to capture images, a sequence of images, videos, and so forth. This includes sensors that convert optical input into images, where optical input can be visible light (like in a camera), radio waves, microwaves, terahertz waves, ultraviolet light, infrared light, x-rays, gamma rays, and/or any other light spectrum. This also includes both 2D and 3D sensors. Examples of image sensor technologies may include: CCD, CMOS, NMOS, and so forth. 3D sensors may be implemented using different technologies, including: stereo camera, active stereo camera, time of flight camera, structured light camera, radar, range image camera, and so forth.

In embodiments of the presently disclosed subject matter, one or more stages illustrated in the figures may be executed in a different order and/or one or more groups of stages may be executed simultaneously and vice versa. The figures illustrate a general schematic of the system architecture in accordance embodiments of the presently disclosed subject matter. Each module in the figures can be made up of any combination of software, hardware and/or firmware that performs the functions as defined and explained herein. The modules in the figures may be centralized in one location or dispersed over more than one location.

It should be noted that some examples of the presently disclosed subject matter are not limited in application to the details of construction and the arrangement of the components set forth in the following description or illustrated in the drawings. The invention can be capable of other embodiments or of being practiced or carried out in various ways. Also, it is to be understood that the phraseology and terminology employed herein is for the purpose of description and should not be regarded as limiting.

In this document, an element of a drawing that is not described within the scope of the drawing and is labeled with a numeral that has been described in a previous drawing may have the same use and description as in the previous drawings.

The drawings in this document may not be to any scale. Different figures may use different scales and different scales can be used even within the same drawing, for example different scales for different views of the same object or different scales for the two adjacent objects.

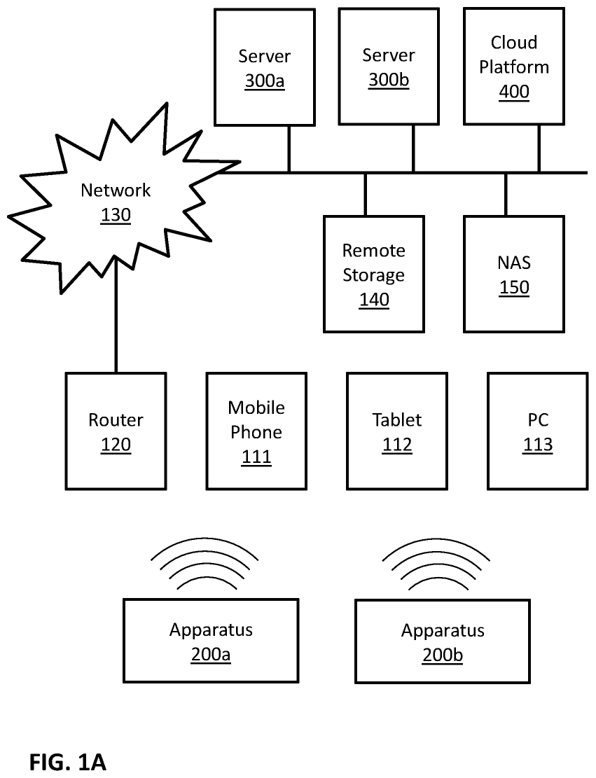

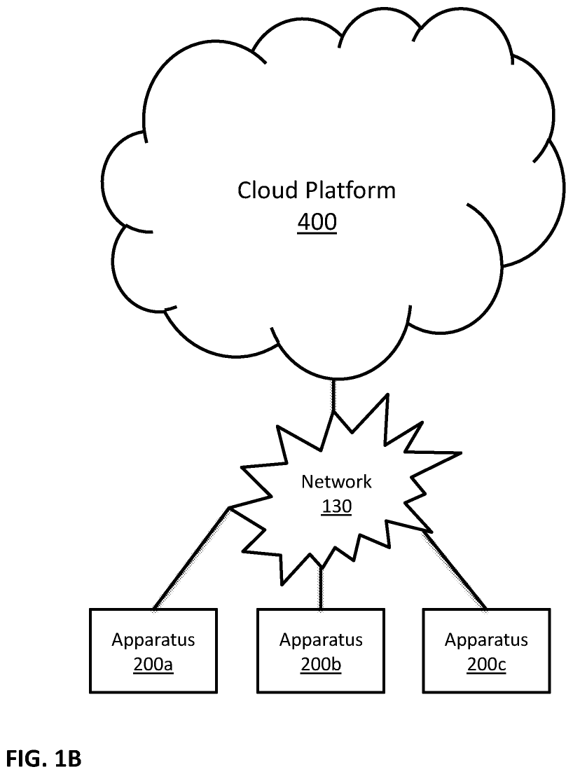

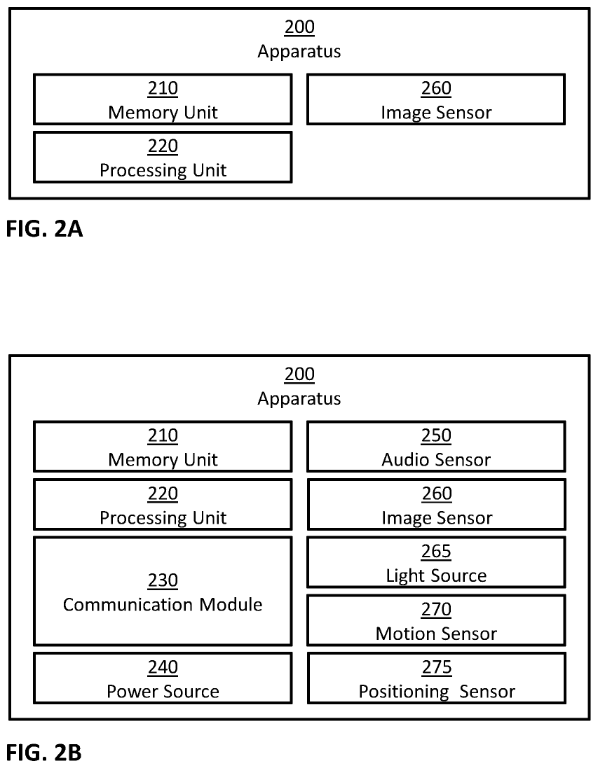

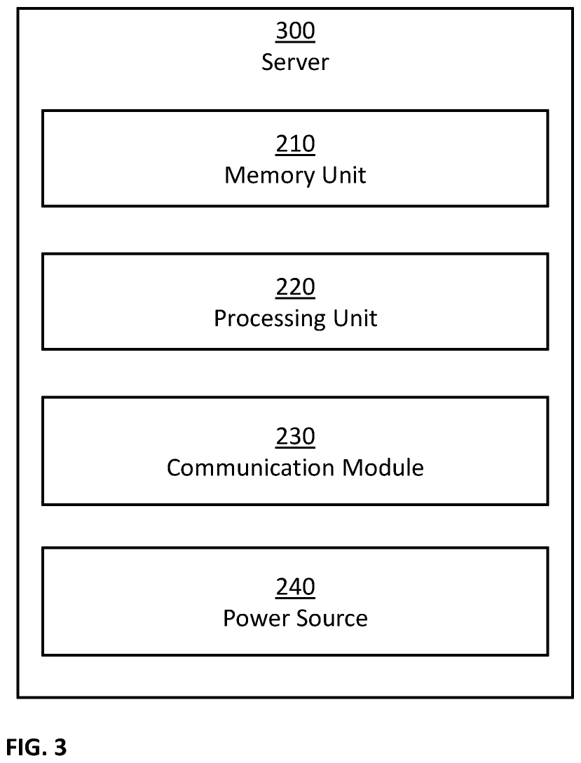

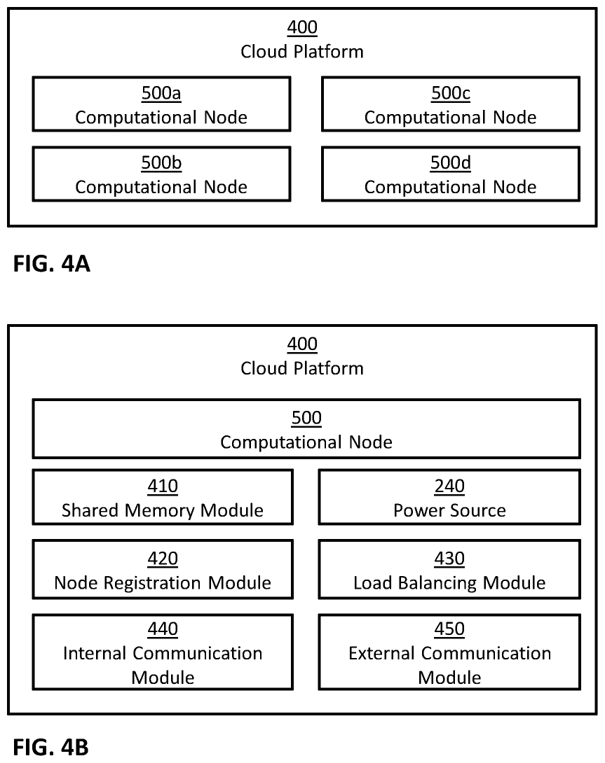

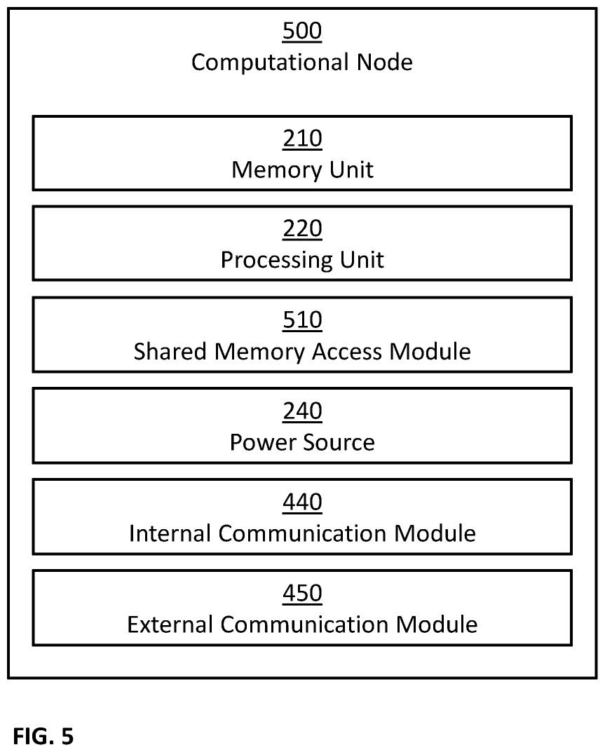

FIG. 1A is a block diagram illustrating a possible implementation of a communicating system. In this example, apparatuses 200a and 200b may communicate with server 300a, with server 300b, with cloud platform 400, with each other, and so forth. Possible implementations of apparatuses 200a and 200b may include apparatus 200 as described in FIGS. 2A and 2B. Possible implementations of servers 300a and 300b may include server 300 as described in FIG. 3. Some possible implementations of cloud platform 400 are described in FIGS. 4A, 4B and 5. In this example apparatuses 200a and 200b may communicate directly with mobile phone 111, tablet 112, and personal computer (PC) 113. Apparatuses 200a and 200b may communicate with local router 120 directly, and/or through at least one of mobile phone 111, tablet 112, and personal computer (PC) 113. In this example, local router 120 may be connected with a communication network 130. Examples of communication network 130 may include the Internet, phone networks, cellular networks, satellite communication networks, private communication networks, virtual private networks (VPN), and so forth. Apparatuses 200a and 200b may connect to communication network 130 through local router 120 and/or directly. Apparatuses 200a and 200b may communicate with other devices, such as servers 300a, server 300b, cloud platform 400, remote storage 140 and network attached storage (NAS) 150, through communication network 130 and/or directly.

FIG. 1B is a block diagram illustrating a possible implementation of a communicating system. In this example, apparatuses 200a, 200b and 200c may communicate with cloud platform 400 and/or with each other through communication network 130. Possible implementations of apparatuses 200a, 200b and 200c may include apparatus 200 as described in FIGS. 2A and 2B. Some possible implementations of cloud platform 400 are described in FIGS. 4A, 4B and 5.

FIGS. 1A and 1B illustrate some possible implementations of a communication system. In some embodiments, other communication systems that enable communication between apparatus 200 and server 300 may be used. In some embodiments, other communication systems that enable communication between apparatus 200 and cloud platform 400 may be used. In some embodiments, other communication systems that enable communication among a plurality of apparatuses 200 may be used.

FIG. 2A is a block diagram illustrating a possible implementation of apparatus 200. In this example, apparatus 200 may comprise: one or more memory units 210, one or more processing units 220, and one or more image sensors 260. In some implementations, apparatus 200 may comprise additional components, while some components listed above may be excluded.

FIG. 2B is a block diagram illustrating a possible implementation of apparatus 200. In this example, apparatus 200 may comprise: one or more memory units 210, one or more processing units 220, one or more communication modules 230, one or more power sources 240, one or more audio sensors 250, one or more image sensors 260, one or more light sources 265, one or more motion sensors 270, and one or more positioning sensors 275. In some implementations, apparatus 200 may comprise additional components, while some components listed above may be excluded. For example, in some implementations apparatus 200 may also comprise at least one of the following: one or more barometers; one or more user input devices; one or more output devices; and so forth. In another example, in some implementations at least one of the following may be excluded from apparatus 200: memory units 210, communication modules 230, power sources 240, audio sensors 250, image sensors 260, light sources 265, motion sensors 270, and positioning sensors 275.

In some embodiments, one or more power sources 240 may be configured to: power apparatus 200; power server 300; power cloud platform 400; and/or power computational node 500. Possible implementation examples of power sources 240 may include: one or more electric batteries; one or more capacitors; one or more connections to external power sources; one or more power convertors; any combination of the above; and so forth.

In some embodiments, the one or more processing units 220 may be configured to execute software programs. For example, processing units 220 may be configured to execute software programs stored on the memory units 210. In some cases, the executed software programs may store information in memory units 210. In some cases, the executed software programs may retrieve information from the memory units 210. Possible implementation examples of the processing units 220 may include: one or more single core processors, one or more multicore processors; one or more controllers; one or more application processors; one or more system on a chip processors; one or more central processing units; one or more graphical processing units; one or more neural processing units; any combination of the above; and so forth.

In some embodiments, the one or more communication modules 230 may be configured to receive and transmit information. For example, control signals may be transmitted and/or received through communication modules 230. In another example, information received though communication modules 230 may be stored in memory units 210. In an additional example, information retrieved from memory units 210 may be transmitted using communication modules 230. In another example, input data may be transmitted and/or received using communication modules 230. Examples of such input data may include: input data inputted by a user using user input devices; information captured using one or more sensors; and so forth. Examples of such sensors may include: audio sensors 250; image sensors 260; motion sensors 270; positioning sensors 275; chemical sensors; temperature sensors; barometers; and so forth.

In some embodiments, the one or more audio sensors 250 may be configured to capture audio by converting sounds to digital information. Some non-limiting examples of audio sensors 250 may include: microphones, unidirectional microphones, bidirectional microphones, cardioid microphones, omnidirectional microphones, onboard microphones, wired microphones, wireless microphones, any combination of the above, and so forth. In some examples, the captured audio may be stored in memory units 210. In some additional examples, the captured audio may be transmitted using communication modules 230, for example to other computerized devices, such as server 300, cloud platform 400, computational node 500, and so forth. In some examples, processing units 220 may control the above processes. For example, processing units 220 may control at least one of: capturing of the audio; storing the captured audio; transmitting of the captured audio; and so forth. In some cases, the captured audio may be processed by processing units 220. For example, the captured audio may be compressed by processing units 220; possibly followed: by storing the compressed captured audio in memory units 210; by transmitted the compressed captured audio using communication modules 230; and so forth. In another example, the captured audio may be processed using speech recognition algorithms. In another example, the captured audio may be processed using speaker recognition algorithms.

In some embodiments, the one or more image sensors 260 may be configured to capture visual information by converting light to: images; sequence of images; videos; 3D images; sequence of 3D images; 3D videos; and so forth. In some examples, the captured visual information may be stored in memory units 210. In some additional examples, the captured visual information may be transmitted using communication modules 230, for example to other computerized devices, such as server 300, cloud platform 400, computational node 500, and so forth. In some examples, processing units 220 may control the above processes. For example, processing units 220 may control at least one of: capturing of the visual information; storing the captured visual information; transmitting of the captured visual information; and so forth. In some cases, the captured visual information may be processed by processing units 220. For example, the captured visual information may be compressed by processing units 220; possibly followed: by storing the compressed captured visual information in memory units 210; by transmitted the compressed captured visual information using communication modules 230; and so forth. In another example, the captured visual information may be processed in order to: detect objects, detect events, detect action, detect face, detect people, recognize person, and so forth.

In some embodiments, the one or more light sources 265 may be configured to emit light, for example in order to enable better image capturing by image sensors 260. In some examples, the emission of light may be coordinated with the capturing operation of image sensors 260. In some examples, the emission of light may be continuous. In some examples, the emission of light may be performed at selected times. The emitted light may be visible light, infrared light, x-rays, gamma rays, and/or in any other light spectrum. In some examples, image sensors 260 may capture light emitted by light sources 265, for example in order to capture 3D images and/or 3D videos using active stereo method.

In some embodiments, the one or more motion sensors 270 may be configured to perform at least one of the following: detect motion of objects in the environment of apparatus 200; measure the velocity of objects in the environment of apparatus 200; measure the acceleration of objects in the environment of apparatus 200; detect motion of apparatus 200; measure the velocity of apparatus 200; measure the acceleration of apparatus 200; and so forth. In some implementations, the one or more motion sensors 270 may comprise one or more accelerometers configured to detect changes in proper acceleration and/or to measure proper acceleration of apparatus 200. In some implementations, the one or more motion sensors 270 may comprise one or more gyroscopes configured to detect changes in the orientation of apparatus 200 and/or to measure information related to the orientation of apparatus 200. In some implementations, motion sensors 270 may be implemented using image sensors 260, for example by analyzing images captured by image sensors 260 to perform at least one of the following tasks: track objects in the environment of apparatus 200; detect moving objects in the environment of apparatus 200; measure the velocity of objects in the environment of apparatus 200; measure the acceleration of objects in the environment of apparatus 200; measure the velocity of apparatus 200, for example by calculating the egomotion of image sensors 260; measure the acceleration of apparatus 200, for example by calculating the egomotion of image sensors 260; and so forth. In some implementations, motion sensors 270 may be implemented using image sensors 260 and light sources 265, for example by implementing a LIDAR using image sensors 260 and light sources 265. In some implementations, motion sensors 270 may be implemented using one or more RADARs. In some examples, information captured using motion sensors 270: may be stored in memory units 210, may be processed by processing units 220, may be transmitted and/or received using communication modules 230, and so forth.

In some embodiments, the one or more positioning sensors 275 may be configured to obtain positioning information of apparatus 200, to detect changes in the position of apparatus 200, and/or to measure the position of apparatus 200. In some examples, positioning sensors 275 may be implemented using one of the following technologies: Global Positioning System (GPS), GLObal NAvigation Satellite System (GLONASS), Galileo global navigation system, BeiDou navigation system, other Global Navigation Satellite Systems (GNSS), Indian Regional Navigation Satellite System (IRNSS), Local Positioning Systems (LPS), Real-Time Location Systems (RTLS), Indoor Positioning System (IPS), Wi-Fi based positioning systems, cellular triangulation, and so forth. In some examples, information captured using positioning sensors 275 may be stored in memory units 210, may be processed by processing units 220, may be transmitted and/or received using communication modules 230, and so forth.

In some embodiments, the one or more chemical sensors may be configured to perform at least one of the following: measure chemical properties in the environment of apparatus 200; measure changes in the chemical properties in the environment of apparatus 200; detect the present of chemicals in the environment of apparatus 200; measure the concentration of chemicals in the environment of apparatus 200. Examples of such chemical properties may include: pH level, toxicity, temperature, and so forth. Examples of such chemicals may include: electrolytes, particular enzymes, particular hormones, particular proteins, smoke, carbon dioxide, carbon monoxide, oxygen, ozone, hydrogen, hydrogen sulfide, and so forth. In some examples, information captured using chemical sensors may be stored in memory units 210, may be processed by processing units 220, may be transmitted and/or received using communication modules 230, and so forth.

In some embodiments, the one or more temperature sensors may be configured to detect changes in the temperature of the environment of apparatus 200 and/or to measure the temperature of the environment of apparatus 200. In some examples, information captured using temperature sensors may be stored in memory units 210, may be processed by processing units 220, may be transmitted and/or received using communication modules 230, and so forth.

In some embodiments, the one or more barometers may be configured to detect changes in the atmospheric pressure in the environment of apparatus 200 and/or to measure the atmospheric pressure in the environment of apparatus 200. In some examples, information captured using the barometers may be stored in memory units 210, may be processed by processing units 220, may be transmitted and/or received using communication modules 230, and so forth.

In some embodiments, the one or more user input devices may be configured to allow one or more users to input information. In some examples, user input devices may comprise at least one of the following: a keyboard, a mouse, a touch pad, a touch screen, a joystick, a microphone, an image sensor, and so forth. In some examples, the user input may be in the form of at least one of: text, sounds, speech, hand gestures, body gestures, tactile information, and so forth. In some examples, the user input may be stored in memory units 210, may be processed by processing units 220, may be transmitted and/or received using communication modules 230, and so forth.

In some embodiments, the one or more user output devices may be configured to provide output information to one or more users. In some examples, such output information may comprise of at least one of: notifications, feedbacks, reports, and so forth. In some examples, user output devices may comprise at least one of: one or more audio output devices; one or more textual output devices; one or more visual output devices; one or more tactile output devices; and so forth. In some examples, the one or more audio output devices may be configured to output audio to a user, for example through: a headset, a set of speakers, and so forth. In some examples, the one or more visual output devices may be configured to output visual information to a user, for example through: a display screen, an augmented reality display system, a printer, a LED indicator, and so forth. In some examples, the one or more tactile output devices may be configured to output tactile feedbacks to a user, for example through vibrations, through motions, by applying forces, and so forth. In some examples, the output may be provided: in real time, offline, automatically, upon request, and so forth. In some examples, the output information may be read from memory units 210, may be provided by a software executed by processing units 220, may be transmitted and/or received using communication modules 230, and so forth.

FIG. 3 is a block diagram illustrating a possible implementation of server 300. In this example, server 300 may comprise: one or more memory units 210, one or more processing units 220, one or more communication modules 230, and one or more power sources 240. In some implementations, server 300 may comprise additional components, while some components listed above may be excluded. For example, in some implementations server 300 may also comprise at least one of the following: one or more user input devices; one or more output devices; and so forth. In another example, in some implementations at least one of the following may be excluded from server 300: memory units 210, communication modules 230, and power sources 240.

FIG. 4A is a block diagram illustrating a possible implementation of cloud platform 400. In this example, cloud platform 400 may comprise computational node 500a, computational node 500b, computational node 500c and computational node 500d. In some examples, a possible implementation of computational nodes 500a, 500b, 500c and 500d may comprise server 300 as described in FIG. 3. In some examples, a possible implementation of computational nodes 500a, 500b, 500c and 500d may comprise computational node 500 as described in FIG. 5.

FIG. 4B is a block diagram illustrating a possible implementation of cloud platform 400. In this example, cloud platform 400 may comprise: one or more computational nodes 500, one or more shared memory modules 410, one or more power sources 240, one or more node registration modules 420, one or more load balancing modules 430, one or more internal communication modules 440, and one or more external communication modules 450. In some implementations, cloud platform 400 may comprise additional components, while some components listed above may be excluded. For example, in some implementations cloud platform 400 may also comprise at least one of the following: one or more user input devices; one or more output devices; and so forth. In another example, in some implementations at least one of the following may be excluded from cloud platform 400: shared memory modules 410, power sources 240, node registration modules 420, load balancing modules 430, internal communication modules 440, and external communication modules 450.

FIG. 5 is a block diagram illustrating a possible implementation of computational node 500. In this example, computational node 500 may comprise: one or more memory units 210, one or more processing units 220, one or more shared memory access modules 510, one or more power sources 240, one or more internal communication modules 440, and one or more external communication modules 450. In some implementations, computational node 500 may comprise additional components, while some components listed above may be excluded. For example, in some implementations computational node 500 may also comprise at least one of the following: one or more user input devices; one or more output devices; and so forth. In another example, in some implementations at least one of the following may be excluded from computational node 500: memory units 210, shared memory access modules 510, power sources 240, internal communication modules 440, and external communication modules 450.

In some embodiments, internal communication modules 440 and external communication modules 450 may be implemented as a combined communication module, such as communication modules 230. In some embodiments, one possible implementation of cloud platform 400 may comprise server 300. In some embodiments, one possible implementation of computational node 500 may comprise server 300. In some embodiments, one possible implementation of shared memory access modules 510 may comprise using internal communication modules 440 to send information to shared memory modules 410 and/or receive information from shared memory modules 410. In some embodiments, node registration modules 420 and load balancing modules 430 may be implemented as a combined module.

In some embodiments, the one or more shared memory modules 410 may be accessed by more than one computational node. Therefore, shared memory modules 410 may allow information sharing among two or more computational nodes 500. In some embodiments, the one or more shared memory access modules 510 may be configured to enable access of computational nodes 500 and/or the one or more processing units 220 of computational nodes 500 to shared memory modules 410. In some examples, computational nodes 500 and/or the one or more processing units 220 of computational nodes 500, may access shared memory modules 410, for example using shared memory access modules 510, in order to perform at least one of: executing software programs stored on shared memory modules 410, store information in shared memory modules 410, retrieve information from the shared memory modules 410.

In some embodiments, the one or more node registration modules 420 may be configured to track the availability of the computational nodes 500. In some examples, node registration modules 420 may be implemented as: a software program, such as a software program executed by one or more of the computational nodes 500; a hardware solution; a combined software and hardware solution; and so forth. In some implementations, node registration modules 420 may communicate with computational nodes 500, for example using internal communication modules 440. In some examples, computational nodes 500 may notify node registration modules 420 of their status, for example by sending messages: at computational node 500 startup; at computational node 500 shutdown; at constant intervals; at selected times; in response to queries received from node registration modules 420; and so forth. In some examples, node registration modules 420 may query about computational nodes 500 status, for example by sending messages: at node registration module 420 startup; at constant intervals; at selected times; and so forth.

In some embodiments, the one or more load balancing modules 430 may be configured to divide the work load among computational nodes 500. In some examples, load balancing modules 430 may be implemented as: a software program, such as a software program executed by one or more of the computational nodes 500; a hardware solution; a combined software and hardware solution; and so forth. In some implementations, load balancing modules 430 may interact with node registration modules 420 in order to obtain information regarding the availability of the computational nodes 500. In some implementations, load balancing modules 430 may communicate with computational nodes 500, for example using internal communication modules 440. In some examples, computational nodes 500 may notify load balancing modules 430 of their status, for example by sending messages: at computational node 500 startup; at computational node 500 shutdown; at constant intervals; at selected times; in response to queries received from load balancing modules 430; and so forth. In some examples, load balancing modules 430 may query about computational nodes 500 status, for example by sending messages: at load balancing module 430 startup; at constant intervals; at selected times; and so forth.

In some embodiments, the one or more internal communication modules 440 may be configured to receive information from one or more components of cloud platform 400, and/or to transmit information to one or more components of cloud platform 400. For example, control signals and/or synchronization signals may be sent and/or received through internal communication modules 440. In another example, input information for computer programs, output information of computer programs, and/or intermediate information of computer programs, may be sent and/or received through internal communication modules 440. In another example, information received though internal communication modules 440 may be stored in memory units 210, in shared memory units 410, and so forth. In an additional example, information retrieved from memory units 210 and/or shared memory units 410 may be transmitted using internal communication modules 440. In another example, input data may be transmitted and/or received using internal communication modules 440. Examples of such input data may include input data inputted by a user using user input devices.

In some embodiments, the one or more external communication modules 450 may be configured to receive and/or to transmit information. For example, control signals may be sent and/or received through external communication modules 450. In another example, information received though external communication modules 450 may be stored in memory units 210, in shared memory units 410, and so forth. In an additional example, information retrieved from memory units 210 and/or shared memory units 410 may be transmitted using external communication modules 450. In another example, input data may be transmitted and/or received using external communication modules 450. Examples of such input data may include: input data inputted by a user using user input devices; information captured from the environment of apparatus 200 using one or more sensors; and so forth. Examples of such sensors may include: audio sensors 250; image sensors 260; motion sensors 270; positioning sensors 275; chemical sensors; temperature sensors; barometers; and so forth.

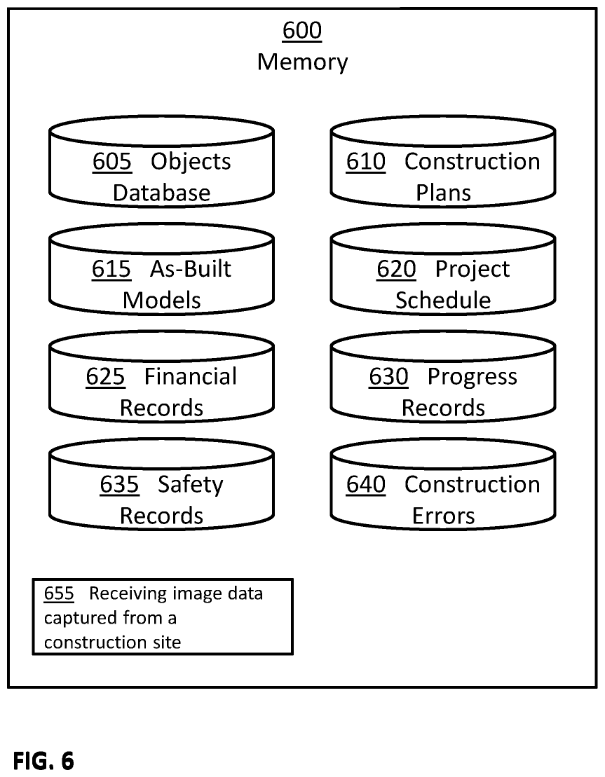

FIG. 6 illustrates an exemplary embodiment of memory 600 storing a plurality of modules. In some examples, memory 600 may be separate from and/or integrated with memory units 210, separate from and/or integrated with memory units 410, and so forth. In some examples, memory 600 may be included in a single device, for example in apparatus 200, in server 300, in cloud platform 400, in computational node 500, and so forth. In some examples, memory 600 may be distributed across several devices. Memory 600 may store more or fewer modules than those shown in FIG. 6. In this example, memory 600 may comprise: objects database 605, construction plans 610, as-built models 615, project schedules 620, financial records 625, progress records 630, safety records 635, construction errors 640, and Module 655 for receiving image data captured from a construction site.

In some embodiments, objects database 605 may comprise information related to objects associated with one or more construction sites. For example, the objects may include objects planned to be used in a construction site, objects ordered for a construction site, objects arrived at a construction site and awaiting to be used and/or installed, objects used in a construction site, objects installed in a construction site, and so forth. In some examples, the information related to an object in database 605 may include properties of the object, type, brand, configuration, dimensions, weight, price, supplier, manufacturer, identifier of related construction site, location (for example, within the construction site), time of planned arrival, time of actual arrival, time of usage, time of installation, actions need to be taken that involves the object, actions performed using and/or on the object, people associated with the actions (such as persons that need to perform an action, persons that performed an action, persons that monitor the action, persons that approve the action, etc.), tools associated with the actions (such as tools required to perform an action, tools used to perform the action, etc.), quality, quality of installation, other objects used in conjunction with the object, and so forth. In some examples, elements in objects database 605 may be indexed and/or searchable, for example using a database, using an indexing data structure, and so forth.

In some embodiments, construction plans 610 may comprise documents, drawings, models, representations, specifications, measurements, bill of materials, architectural plans, architectural drawings, floor plans, 2D architectural plans, 3D architectural plans, construction drawings, feasibility plans, demolition plans, permit plans, mechanical plans, electrical plans, space plans, elevations, sections, renderings, computer-aided design data, Building Information Modeling (BIM) models, and so forth, indicating design intention for one or more construction sites and/or one or more portions of one or more construction sites. Construction plans 610 may be digitally stored in memory 600, as described above.

In some embodiments, as-built models 615 may comprise documents, drawings, models, representations, specifications, measurements, list of materials, architectural drawings, floor plans, 2D drawings, 3D drawings, elevations, sections, renderings, computer-aided design data, BIM models, and so forth, representing one or more buildings or spaces as they were actually constructed. As-built models 615 may be digitally stored in memory 600, as described above.

In some embodiments, project schedules 620 may comprise details of planned tasks, milestones, activities, deliverables, expected task start time, expected task duration, expected task completion date, resource allocation to tasks, linkages of dependencies between tasks, and so forth, related to one or more construction sites. Project schedules 620 may be digitally stored in memory 600, as described above.

In some embodiments, financial records 625 may comprise information, records and documents related to financial transactions, invoices, payment receipts, bank records, work orders, supply orders, delivery receipts, rental information, salaries information, financial forecasts, financing details, loans, insurance policies, and so forth, associated with one or more construction sites. Financial records 625 may be digitally stored in memory 600, as described above.

In some embodiments, progress records 630 may comprise information, records and documents related to tasks performed in one or more construction sites, such as actual task start time, actual task duration, actual task completion date, items used, item affected, resources used, results, and so forth. Progress records 630 may be digitally stored in memory 600, as described above.

In some embodiments, safety records 635 may include information, records and documents related to safety issues (such as hazards, accidents, near accidents, safety related events, etc.) associated with one or more construction sites. Safety records 635 may be digitally stored in memory 600, as described above.

In some embodiments, construction errors 640 may include information, records and documents related to construction errors (such as execution errors, divergence from construction plans, improper alignment of items, improper placement or items, improper installation of items, concrete of low quality, missing item, excess item, and so forth) associated with one or more construction sites. Construction errors 640 may be digitally stored in memory 600, as described above.

In some embodiments, Module 655 may comprise receiving image data captured from a construction site, captured from a particular section of a construction site, captured from a construction site at a particular time or in a particular time period, captured from a particular section of a construction site at a particular time or in a particular time period, and so forth. For example, Module 655 may read the image data from memory, for example from memory units 210, shared memory modules 410, memory 600, and so forth. In another example, Module 655 may receive the image data from an external device, from another process, and so forth. In yet another example, Module 655 may receive the first information and/or the second information using one or more communication devices, such as communication modules 230, internal communication modules 440, external communication modules 450, and so forth. In an additional example, Module 655 may comprise capturing the image data from the construction site using at least one image sensor, such as image sensors 260. Some non-limiting examples of such image data may include: one or more images; one or more portions of one or more images; sequence of images; one or more video clips; one or more portions of one or more video clips; one or more video streams; one or more portions of one or more video streams; one or more 3D images; one or more portions of one or more 3D images; sequence of 3D images; one or more 3D video clips; one or more portions of one or more 3D video clips; one or more 3D video streams; one or more portions of one or more 3D video streams; one or more 360 images; one or more portions of one or more 360 images; sequence of 360 images; one or more 360 video clips; one or more portions of one or more 360 video clips; one or more 360 video streams; one or more portions of one or more 360 video streams; information based, at least in part, on any of the above; any combination of the above; and so forth.

In some examples, Module 655 may comprise receiving image data captured from a construction site (and/or capturing the image data from the construction site) using at least one wearable image sensor, such as wearable version of apparatus 200 and/or wearable version of image sensor 260. For example, the wearable image sensors may be configured to be worn by construction workers and/or other persons in the construction site. For example, the wearable image sensor may be physically connected and/or integral to a garment, physically connected and/or integral to a belt, physically connected and/or integral to a wrist strap, physically connected and/or integral to a necklace, physically connected and/or integral to a helmet, and so forth.

In some examples, Module 655 may comprise receiving image data captured from a construction site (and/or capturing the image data from the construction site) using at least one stationary image sensor, such as stationary version of apparatus 200 and/or stationary version of image sensor 260. For example, the stationary image sensors may be configured to be mounted to ceilings, to walls, to doorways, to floors, and so forth. For example, a stationary image sensor may be configured to be mounted to a ceiling, for example substantially at the center of the ceiling (for example, less than two meters from the center of the ceiling, less than one meter from the center of the ceiling, less than half a meter from the center of the ceiling, and so forth), adjunct to an electrical box in the ceiling, at a position in the ceiling corresponding to a planned connection of a light fixture to the ceiling, and so forth. In another example, two or more stationary image sensors may be mounted to a ceiling in a way that ensures that the fields of view of the two cameras include all walls of the room.

In some examples, Module 655 may comprise obtaining image data captured from a construction site (and/or capturing the image data from the construction site) using at least one mobile image sensor, such as mobile version of apparatus 200 and/or mobile version of image sensor 260. For example, mobile image sensors may be operated by construction workers and/or other persons in the construction site to capture image data of the construction site. In another example, mobile image sensors may be part of a robot configured to move through the construction site and capture image data of the construction site. In yet another example, mobile image sensors may be part of a drone configured to fly through the construction site and capture image data of the construction site.

In some examples, Module 655 may comprise, in addition or alternatively to obtaining image data and/or other input data, obtaining motion information captured using one or more motion sensors, for example using motion sensors 270. Examples of such motion information may include: indications related to motion of objects; measurements related to the velocity of objects; measurements related to the acceleration of objects; indications related to motion of motion sensor 270; measurements related to the velocity of motion sensor 270; measurements related to the acceleration of motion sensor 270; information based, at least in part, on any of the above; any combination of the above; and so forth.

In some examples, Module 655 may comprise, in addition or alternatively to obtaining image data and/or other input data, obtaining position information captured using one or more positioning sensors, for example using positioning sensors 275. Examples of such position information may include: indications related to the position of positioning sensors 275; indications related to changes in the position of positioning sensors 275; measurements related to the position of positioning sensors 275; indications related to the orientation of positioning sensors 275; indications related to changes in the orientation of positioning sensors 275; measurements related to the orientation of positioning sensors 275; measurements related to changes in the orientation of positioning sensors 275; information based, at least in part, on any of the above; any combination of the above; and so forth.

In some embodiments, a method, such as methods 800, 900 and 1000 may comprise of one or more steps. In some examples, these methods, as well as all individual steps therein, may be performed by various aspects of apparatus 200, server 300, cloud platform 400, computational node 500, and so forth. For example, a system comprising of at least one processor, such as processing units 220, may perform any of these methods as well as all individual steps therein, for example by processing units 220 executing software instructions stored within memory units 210 and/or within shared memory modules 410. In some examples, these methods, as well as all individual steps therein, may be performed by a dedicated hardware. In some examples, computer readable medium, such as a non-transitory computer readable medium, may store data and/or computer implementable instructions for carrying out any of these methods as well as all individual steps therein. Some non-limiting examples of possible execution manners of a method may include continuous execution (for example, returning to the beginning of the method once the method normal execution ends), periodically execution, executing the method at selected times, execution upon the detection of a trigger (some non-limiting examples of such trigger may include a trigger from a user, a trigger from another process, a trigger from an external device, etc.), and so forth.

In some embodiments, machine learning algorithms (also referred to as machine learning models in the present disclosure) may be trained using training examples, for example by Step 814, Step 820, Step 830, Step 920, Step 1014, Step 1020, Step 1030, and in the cases described below. Some non-limiting examples of such machine learning algorithms may include classification algorithms, data regressions algorithms, image segmentation algorithms, visual detection algorithms (such as object detectors, face detectors, person detectors, motion detectors, edge detectors, etc.), visual recognition algorithms (such as face recognition, person recognition, object recognition, etc.), speech recognition algorithms, mathematical embedding algorithms, natural language processing algorithms, support vector machines, random forests, nearest neighbors algorithms, deep learning algorithms, artificial neural network algorithms, convolutional neural network algorithms, recursive neural network algorithms, linear machine learning models, non-linear machine learning models, ensemble algorithms, and so forth. For example, a trained machine learning algorithm may comprise an inference model, such as a predictive model, a classification model, a regression model, a clustering model, a segmentation model, an artificial neural network (such as a deep neural network, a convolutional neural network, a recursive neural network, etc.), a random forest, a support vector machine, and so forth. In some examples, the training examples may include example inputs together with the desired outputs corresponding to the example inputs. Further, in some examples, training machine learning algorithms using the training examples may generate a trained machine learning algorithm, and the trained machine learning algorithm may be used to estimate outputs for inputs not included in the training examples. In some examples, engineers, scientists, processes and machines that train machine learning algorithms may further use validation examples and/or test examples. For example, validation examples and/or test examples may include example inputs together with the desired outputs corresponding to the example inputs, a trained machine learning algorithm and/or an intermediately trained machine learning algorithm may be used to estimate outputs for the example inputs of the validation examples and/or test examples, the estimated outputs may be compared to the corresponding desired outputs, and the trained machine learning algorithm and/or the intermediately trained machine learning algorithm may be evaluated based on a result of the comparison. In some examples, a machine learning algorithm may have parameters and hyper parameters, where the hyper parameters are set manually by a person or automatically by an process external to the machine learning algorithm (such as a hyper parameter search algorithm), and the parameters of the machine learning algorithm are set by the machine learning algorithm according to the training examples. In some implementations, the hyper-parameters are set according to the training examples and the validation examples, and the parameters are set according to the training examples and the selected hyper-parameters.

In some embodiments, trained machine learning algorithms (also referred to as trained machine learning models in the present disclosure) may be used to analyze inputs and generate outputs, for example by Step 814, Step 820, Step 830, Step 920, Step 1014, Step 1020, Step 1030, and in the cases described below. In some examples, a trained machine learning algorithm may be used as an inference model that when provided with an input generates an inferred output. For example, a trained machine learning algorithm may include a classification algorithm, the input may include a sample, and the inferred output may include a classification of the sample (such as an inferred label, an inferred tag, and so forth). In another example, a trained machine learning algorithm may include a regression model, the input may include a sample, and the inferred output may include an inferred value for the sample. In yet another example, a trained machine learning algorithm may include a clustering model, the input may include a sample, and the inferred output may include an assignment of the sample to at least one cluster. In an additional example, a trained machine learning algorithm may include a classification algorithm, the input may include an image, and the inferred output may include a classification of an item depicted in the image. In yet another example, a trained machine learning algorithm may include a regression model, the input may include an image, and the inferred output may include an inferred value for an item depicted in the image (such as an estimated property of the item, such as size, volume, age of a person depicted in the image, cost of a product depicted in the image, and so forth). In an additional example, a trained machine learning algorithm may include an image segmentation model, the input may include an image, and the inferred output may include a segmentation of the image. In yet another example, a trained machine learning algorithm may include an object detector, the input may include an image, and the inferred output may include one or more detected objects in the image and/or one or more locations of objects within the image. In some examples, the trained machine learning algorithm may include one or more formulas and/or one or more functions and/or one or more rules and/or one or more procedures, the input may be used as input to the formulas and/or functions and/or rules and/or procedures, and the inferred output may be based on the outputs of the formulas and/or functions and/or rules and/or procedures (for example, selecting one of the outputs of the formulas and/or functions and/or rules and/or procedures, using a statistical measure of the outputs of the formulas and/or functions and/or rules and/or procedures, and so forth).

In some embodiments, artificial neural networks may be configured to analyze inputs and generate corresponding outputs, for example by Step 814, Step 830, Step 1014, Step 1030, and in the cases described below. Some non-limiting examples of such artificial neural networks may comprise shallow artificial neural networks, deep artificial neural networks, feedback artificial neural networks, feed forward artificial neural networks, autoencoder artificial neural networks, probabilistic artificial neural networks, time delay artificial neural networks, convolutional artificial neural networks, recurrent artificial neural networks, long short term memory artificial neural networks, and so forth. In some examples, an artificial neural network may be configured manually. For example, a structure of the artificial neural network may be selected manually, a type of an artificial neuron of the artificial neural network may be selected manually, a parameter of the artificial neural network (such as a parameter of an artificial neuron of the artificial neural network) may be selected manually, and so forth. In some examples, an artificial neural network may be configured using a machine learning algorithm. For example, a user may select hyper-parameters for the an artificial neural network and/or the machine learning algorithm, and the machine learning algorithm may use the hyper-parameters and training examples to determine the parameters of the artificial neural network, for example using back propagation, using gradient descent, using stochastic gradient descent, using mini-batch gradient descent, and so forth. In some examples, an artificial neural network may be created from two or more other artificial neural networks by combining the two or more other artificial neural networks into a single artificial neural network.

In some embodiments, analyzing image data (for example by the methods, steps and modules described herein, such as Step 814) may comprise analyzing the image data to obtain a preprocessed image data, and subsequently analyzing the image data and/or the preprocessed image data to obtain the desired outcome. Some non-limiting examples of such image data may include one or more images, videos, frames, footages, 2D image data, 3D image data, and so forth. One of ordinary skill in the art will recognize that the followings are examples, and that the image data may be preprocessed using other kinds of preprocessing methods. In some examples, the image data may be preprocessed by transforming the image data using a transformation function to obtain a transformed image data, and the preprocessed image data may comprise the transformed image data. For example, the transformed image data may comprise one or more convolutions of the image data. For example, the transformation function may comprise one or more image filters, such as low-pass filters, high-pass filters, band-pass filters, all-pass filters, and so forth. In some examples, the transformation function may comprise a nonlinear function. In some examples, the image data may be preprocessed by smoothing at least parts of the image data, for example using Gaussian convolution, using a median filter, and so forth. In some examples, the image data may be preprocessed to obtain a different representation of the image data. For example, the preprocessed image data may comprise: a representation of at least part of the image data in a frequency domain; a Discrete Fourier Transform of at least part of the image data; a Discrete Wavelet Transform of at least part of the image data; a time/frequency representation of at least part of the image data; a representation of at least part of the image data in a lower dimension; a lossy representation of at least part of the image data; a lossless representation of at least part of the image data; a time ordered series of any of the above; any combination of the above; and so forth. In some examples, the image data may be preprocessed to extract edges, and the preprocessed image data may comprise information based on and/or related to the extracted edges. In some examples, the image data may be preprocessed to extract image features from the image data. Some non-limiting examples of such image features may comprise information based on and/or related to: edges; corners; blobs; ridges; Scale Invariant Feature Transform (SIFT) features; temporal features; and so forth.

In some embodiments, analyzing image data (for example by the methods, steps and modules described herein, such as Step 814) may comprise analyzing the image data and/or the preprocessed image data using one or more rules, functions, procedures, artificial neural networks, object detection algorithms, face detection algorithms, visual event detection algorithms, action detection algorithms, motion detection algorithms, background subtraction algorithms, inference models, and so forth. Some non-limiting examples of such inference models may include: an inference model preprogrammed manually; a classification model; a regression model; a result of training algorithms, such as machine learning algorithms and/or deep learning algorithms, on training examples, where the training examples may include examples of data instances, and in some cases, a data instance may be labeled with a corresponding desired label and/or result; and so forth.

In some embodiments, analyzing image data (for example by the methods, steps and modules described herein, such as Step 814) may comprise analyzing pixels, voxels, point cloud, range data, etc. included in the image data.

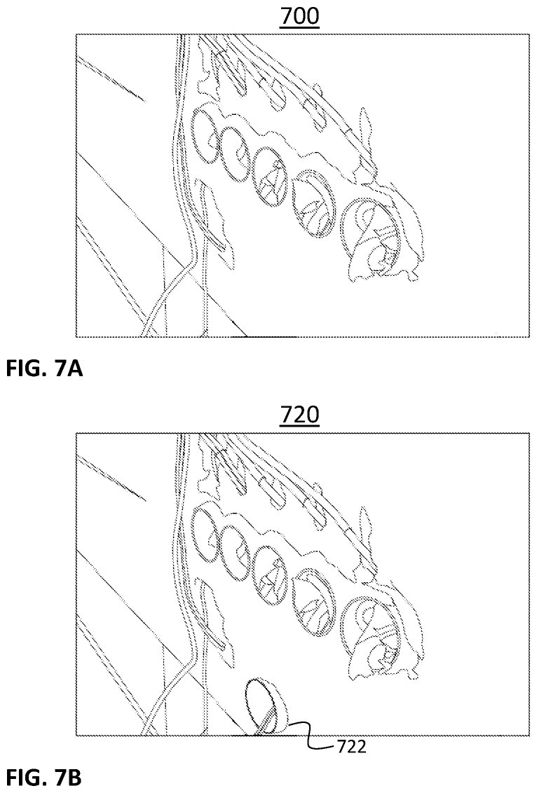

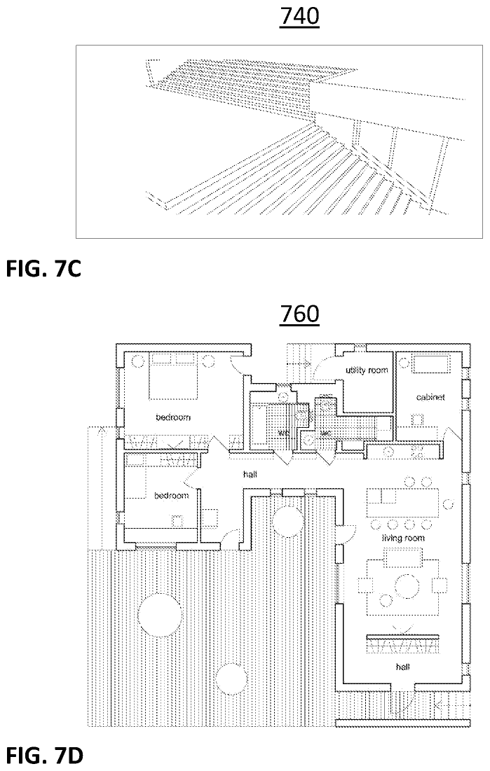

FIGS. 7A, 7B and 7C are schematic illustrations of example images captured from construction sites. In this example, FIG. 7A illustrates an example of image 700 of a first section of a construction site captured at a first time period, FIG. 7B illustrates an example of image 720 of the first section of a construction site at captured at a second time period, and FIG. 7C illustrates an example of image 740 of the second section of a construction site, which may have been captured at the first time period, at the second time period, at a different time period, and so forth. In this example, image 720 includes a depiction of element 722 installed in the construction site after the capturing of image 700.

FIG. 7D is a schematic illustration of an example construction plan 760. In this example, construction plan 760 includes a floor plan. In some examples, construction plan 760 may include three-dimensional construction plans. In some examples, construction plan 760 may include BIM information including construction plans. For example, construction plan 760 may include one or more industry Foundation Classes (IFC) files including construction plans.

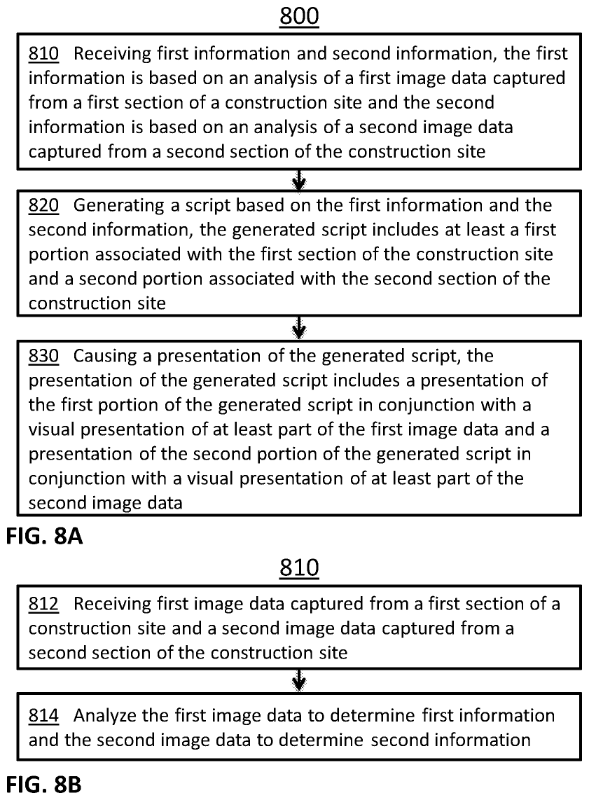

FIG. 8A illustrates an example of a method 800 for generating and presenting scripts related to different sections of construction sites. In this example, method 800 may comprise: receiving first information and second information (Step 810), the first information may be based on an analysis of a first image data captured from a first section of a construction site and the second information may be based on an analysis of a second image data captured from a second section of the construction site; generating a script based on the first information and the second information (Step 820), the generated script may include at least a first portion associated with the first section of the construction site and a second portion associated with the second section of the construction site; and causing a presentation of the generated script (Step 830), the presentation of the generated script may include a presentation of the first portion of the generated script in conjunction with a visual presentation of at least part of the first image data and a presentation of the second portion of the generated script in conjunction with a visual presentation of at least part of the second image data. In some implementations, method 800 may comprise one or more additional steps, while some of the steps listed above may be modified or excluded. For example, Step 830 may be excluded from method 800. In some implementations, one or more steps illustrated in FIG. 8A may be executed in a different order and/or one or more groups of steps may be executed simultaneously and vice versa.

In some embodiments, the first information received by Step 810 may be or include information on a status of the first section of the construction site, and/or the second information received by Step 810 may be or include information on a status of the second section of the construction site. In some embodiments, the first section of the construction site of method 800 may be a first room, and/or the second section of the construction site of method 800 may be a second room, the second room may differ from the first room. In some embodiments, the first section of the construction site of method 800 may be a first wall, and/or the second section of the construction site of method 800 may be a second wall, the second wall may differ from the first wall. In some embodiments, the first section of the construction site of method 800 may be a first story, and/or the second section of the construction site of method 800 may be a second story, the second story may differ from the first story.

In some embodiments, Step 810 may comprise receiving first information and/or second information. The first information may be based on an analysis of a first image data captured from a first section of a construction site and/or the second information may be based on an analysis of a second image data captured from a second section of the construction site, the second section of the construction site may differ from the first section of the construction site. For example, Step 810 may read the first information and/or the second information from memory, for example from memory units 210, shared memory modules 410, memory 600, and so forth. In another example, Step 810 may receive the first information and/or the second information from an external device, from another process, and so forth. In another example, Step 810 may receive the first information and/or the second information using one or more communication devices, such as communication modules 230, internal communication modules 440, external communication modules 450, and so forth. In some examples, the first information may include values of pixels from the first image data, information based on the values of pixels from the first image data, and so forth. In some examples, the second information may include values of pixels from the second image data, information based on the values of pixels from the second image data, and so forth. In some examples, the first image data may include at least one image, and the first information may include at least one of a portion of the at least one image, a transformation of the portion, information based on an analysis of the portion, and so forth. In some examples, the second image data may include at least one image, and the second information may include at least one of a portion of the at least one image, a transformation of the portion, information based on an analysis of the portion, and so forth. In some examples, Step 810 may generate the first information based on an analysis of the first image data and/or may generate the second information based on an analysis of the second image data. One possible implementation of Step 810 is illustrated in FIG. 8B.

FIG. 8B illustrates a non-limiting example of a possible implementation of Step 810. In this example, Step 810 may comprise: receiving first image data captured from a first section of a construction site and a second image data captured from a second section of the construction site (Step 812); and analyzing the first image data to determine first information and the second image data to determine second information (Step 814). In some implementations, Step 814 may be executed after and/or simultaneously with Step 812.

In some embodiments, Step 812 may comprise receiving the first image data and/or the second image data. For example, the first image data may include image data captured from the first section of the construction site and/or the second image data may include image data captured from the second section of the construction site. In one example, Step 812 may use Module 655 to receive the first image data and/or to receive the second image data. In one example, the first image data received by Step 812 may include and/or be based on image 700, and the second image data received by Step 812 may include and/or be based on image 740.

In some embodiments, Step 814 may comprise analyzing the first image data received by Step 812 and/or by Step 912 to determine the first information and/or analyzing the second image data received by Step 812 and/or by Step 912 to determine the second information. For example, a machine learning model may be trained using training examples to determine information from image data, and Step 814 may use the trained machine learning model to analyze the first image data received by Step 812 and/or by Step 912 to determine the first information and/or to analyze the second image data received by Step 812 and/or by Step 912 to determine the second information. One example of such training data may include a sample image data, together with a sample of desired information corresponding to the sample image data. In another example, Step 814 may calculate a convolution of at least a portion of the first image data received by Step 812 and/or by Step 912, and may use the calculated convolution to determine the first information. For example, in response to a first value of the calculated convolution, Step 814 may determine one version of the first information, and in response to a second value of the calculated convolution, Step 814 may determine another version of the first information. Similarly, Step 814 may calculate a convolution of at least a portion of the second image data received by Step 812 and/or by Step 912, and may use the calculated convolution to determine the second information. In yet another example, Step 814 may use an object detection algorithm to analyze the first image data received by Step 812 and determine information about objects in the first section of the construction site, or may use an object detection algorithm to analyze the first image data received by Step 912 and determine information about objects present in the construction site during the first time period, and the first information may include and/or be based on the information about the objects. In an additional example, Step 814 may use an event detection algorithm to analyze the first image data received by Step 812 and determine information about events occurring in the first section of the construction site, or may use an event detection algorithm to analyze the first image data received by Step 912 and determine information about events occurring in the construction site during the first time period, and the first information may include and/or be based on the information about the events.

In some embodiments, Step 820 may comprise generating a script based on the first information received by Step 810 and/or the second information received by Step 810. The generated script may include at least a first portion associated with the first section of the construction site and/or a second portion associated with the second section of the construction site. In some examples, Step 820 may analyze the first information received by Step 810 and/or the second information received by Step 810 to generate the script. For example, a machine learning model may be trained using training examples to generate scripts from information, and Step 820 may use the trained machine learning model, the first information received by Step 810 and/or the second information received by Step 810 to generate the script. One example of such training example may include sample information, together with a corresponding desired script. In another example, in response to a first combination of first information and second information, Step 820 may generate a first script, and in response to a second combination of first information and second information, Step 820 may generate a second script, the second script may differ from the first script. In yet another example, the first portion of the script may include information included and/or indicated by in the first information (such as a quantity, a type of object, a status, and so forth, for example a quantity, a type or a status associated with the first section of the construction site) and the second portion of the script may include information included and/or indicated by in the second information (such as a quantity, a type of object, a status, and so forth, for example a quantity, a type or a status associated with the second section of the construction site).

In some examples, Step 820 may further base the generation of the script on at least one of a construction plan associated with the construction site, a project schedule associated with the construction site, a progress record associated with the construction site and a financial record associated with the construction site. For example, Step 820 may base the generation of the script on a first element of the construction plan corresponding to the first section of the construction site and/or on a second element of the construction plan corresponding to the second section of the construction site. In this example, the first portion of the script may include information included and/or indicated by in the first information and information based on the first element of the construction plan, and/or the second portion of the script may include information included and/or indicated by in the second information and information based on the second element of the construction plan. In another example, Step 820 may base the generation of the script on a first task in the project schedule corresponding to the first section of the construction site and/or on a second task in the project schedule corresponding to the second section of the construction site. In this example, the first portion of the script may include information included and/or indicated by in the first information and information based on the first task of the project schedule, and/or the second portion of the script may include information included and/or indicated by in the second information and information based on the second task of the project schedule. In yet another example, Step 820 may base the generation of the script on a first progress indicator in the progress record corresponding to a progress in the first section of the construction site and/or on a second progress indicator in the project schedule corresponding to a progress in the second section of the construction site. In this example, the first portion of the script may include information included and/or indicated by in the first information and information based on the first progress indicator, and/or the second portion of the script may include information included and/or indicated by in the second information and information based on the second progress indicator. In an additional example, Step 820 may base the generation of the script on a first financial transaction in the financial record corresponding to the first section of the construction site and/or on a second financial transaction in the financial record corresponding to the second section of the construction site. In this example, the first portion of the script may include information included and/or indicated by in the first information and information based on the first financial transaction, and/or the second portion of the script may include information included and/or indicated by in the second information and information based on the second financial transaction.

In some examples, the first portion of the script generated by Step 820 may be indicative of a delay at the first section of the construction site, and/or the second portion of the script generated by Step 820 may be indicative of a delay at the second section of the construction site. For example, Step 820 may use the first information together with a project schedule associated with the construction site and/or a progress record associated with the construction site to generate the indication of the delay in the first section of the construction site in the script. In some examples, the first portion of the script generated by Step 820 may be indicative of a completion of work at the first section of the construction site, and/or the second portion of the script generated by Step 820 may be indicative of a completion of work at the second section of the construction site. For example, Step 820 may use the first information and/or a progress record associated with the construction site to generate the indication of the completion of work at the first section of the construction site in the script. In some examples, the first portion of the script generated by Step 820 may be indicative of a construction error at the first section of the construction site, and/or the second portion of the script generated by Step 820 may be indicative of a construction error at the second section of the construction site. For example, Step 820 may use the first information and/or a construction plan associated with the construction site to generate the indication of the construction error at the first section of the construction site in the script. For example, the indication of the construction error at the first section of the construction site may be an indication of a discrepancy between the first section of the construction site and the construction plan. In some examples, the first portion of the script generated by Step 820 may be indicative of a quality issue at the first section of the construction site, and/or the second portion of the script generated by Step 820 may be indicative of a quality issue at the second section of the construction site. Some non-limiting examples of such quality issues may include a usage of a low quality element, a usage of an incompatible element, a problem in an installation of an element, and so forth. In some examples, the first portion of the script generated by Step 820 may be indicative of a safety issue at the first section of the construction site, and the second portion of the script generated by Step 820 may be indicative of a safety issue at the second section of the construction site. Some non-limiting examples of such safety issues may include a failure to use safety equipment, a failure to follow safety guidelines, and so forth. In some examples, the first portion of the script generated by Step 820 may be indicative of a usage of materials at the first section of the construction site, and/or the second portion of the script generated by Step 820 may be indicative of a usage of materials at the second section of the construction site. For example, the script generated by Step 820 may be indicative of a type of the materials used, may be indicative of a quantity of the materials used, may be indicative of a type of usage, may be indicative of a prospective usage of materials in the corresponding section of the construction site, and so forth. In some examples, the first portion of the script generated by Step 820 may be indicative of a material used at the first section of the construction site, and/or the second portion of the script generated by Step 820 may be indicative of a material used at the second section of the construction site. In some examples, the first portion of the script generated by Step 820 may be indicative of a first prospective construction work at the first section of the construction site, and/or the second portion of the script generated by Step 820 may be indicative of a second prospective construction work at the second section of the construction site. For example, Step 820 may use the first information together with a project schedule associated with the construction site to generate the indication of the first prospective construction work at the first section of the construction site in the script. In some examples, the first portion of the script generated by Step 820 may be indicative of a readiness for a prospective construction work at the first section of the construction site, and/or the second portion of the script generated by Step 820 may be indicative of a unreadiness for the prospective construction work at the second section of the construction site. For example, Step 820 may use the first information together with a project schedule associated with the construction site and/or a progress record associated with the construction site to generate the indication of the readiness for the prospective construction work at the first section of the construction site in the script.

In some embodiments, Step 830 may comprise causing a presentation of a generated script that includes at least a first portion associated with first image data and a second portion associated with second image data (such as the script generated by Step 820, the script generated by Step 920, and so forth). The presentation of the generated script may include a presentation of the first portion of the generated script in conjunction with a visual presentation of at least part of the first image data and/or a presentation of the second portion of the generated script in conjunction with a visual presentation of at least part of the second image data. In some examples, the presentation of the first portion of the generated script and/or the presentation of the second portion of the generated script may be audible. For example, the presentation of the generated script may include a video with audible presentation of the first portion of the generated script in conjunction with frames including a visual presentation of at least part of the first image and with audible presentation of the second portion of the generated script in conjunction with frames including a visual presentation of at least part of the second image. In one example, the audible presentation of the generated script may be generated using a text-to-speech algorithm. In some examples, the presentation of the first portion of the generated script may include a presentation of the first portion of the generated script in a textual form in conjunction with the visual presentation of the at least part of the first image data, and/or the presentation of the second portion of the generated script may include a presentation of the second portion of the generated script in textual form in conjunction with the visual presentation of the at least part of the second image data. For example, the presentation of the first portion of the generated script may include a presentation of the first portion of the generated script in subtitles or captions in conjunction with the visual presentation of the at least part of the first image data, and the presentation of the second portion of the generated script may include a presentation of the second portion of the generated script in subtitles or captions in conjunction with the visual presentation of the at least part of the second image data.

In some examples, Step 830 may cause an external device to present the presentation of the generated script (for example, the script generated by Step 820, the script generated by Step 920, etc.), for example by transmitting instructions and/or data to the external device. In some examples, Step 830 may store a media file of the presentation of the generated script (for example, the script generated by Step 820, the script generated by Step 920, etc.) in memory, for example in a format (such as one or more image files, a video file, etc.) enabling another process and/or another device to present the presentation of the script. In some examples, Step 830 may cause the presentation of the generated script (for example, the script generated by Step 820, the script generated by Step 920, etc.) on a display screen, in a virtual reality system, in an augmented reality system, and so forth.

In some embodiments, Step 830 may use the generated script (for example, the script generated by Step 820, the script generated by Step 920, etc.) to generate a visual representation of a synthetic character presenting the script, the presentation of the generated script by the synthetic character may include a presentation of the first portion of the generated script by the synthetic character in conjunction with the visual presentation of the at least part of the first image data and/or may include a presentation of the second portion of the generated script by the synthetic character in conjunction with the visual presentation of the at least part of the second image data. In some examples, the synthetic character may be at least one of a synthetic character of a civil engineer, a synthetic character of financial accountant, a synthetic character of an architect, a synthetic character of a real-estate developer and a synthetic character of an operations manager. In some examples, the synthetic character may be selected (for example, from a plurality of alternative synthetic characters) based on a characteristic of a prospective viewer. In some examples, Generative Adversarial Networks (GAN) may be used to train an artificial neural network to generate, from scripts, visual presentations of synthetic characters presenting scripts, and Step 830 may use the trained artificial neural network to generate, from the generated script (for example, from the script generated by Step 820, from the script generated by Step 920, etc.), the visual representation of the synthetic character presenting the generated script (for example, the script generated by Step 820, the script generated by Step 920, etc.) In some examples, Step 830 may generate a video visualization of the synthetic character presenting the generated script (for example, the script generated by Step 820, the script generated by Step 920, etc.) by using an image of the synthetic character and modifying the lips region of the face of the synthetic character to mimic lips movement (for example, using a lips movement generation algorithm) corresponding to the synthetic character saying the words of the scripts at the same time where audible presentation of the words is presented (for example, audible presentation generated using a text-to-speech algorithm). In some examples, Step 830 may generate a visualization of the synthetic character presenting the generated script (for example, the script generated by Step 820, the script generated by Step 920, etc.) by adding speech bubbles corresponding to the script to images of the synthetic character. In some examples, Step 830 may stitch the visual representation of the synthetic character presenting the generated script (for example, the script generated by Step 820, the script generated by Step 920, etc.) on different backgrounds, such as the visual presentation of the at least part of the first image data and/or the visual presentation of the at least part of the second image data. Different backgrounds may be used while the synthetic character presents different portions of the scripts, for example using a background including at least part of the first image data when the synthetic character presents of the first portion of the generated script and/or using a background including at least part of the second image data when the synthetic character presents of the second portion of the generated script. In some examples, Step 830 may present the visual representation of the synthetic character presenting the generated script (for example, the script generated by Step 820, the script generated by Step 920, etc.) next to different visuals, such as the visual presentation of the at least part of the first image data and/or the visual presentation of the at least part of the second image data. Different visuals may be used while the synthetic character presents different portions of the scripts, for example presenting a visual including at least part of the first image data next to the synthetic character presenting of the first portion of the generated script and/or using a visual including at least part of the second image data next to the synthetic character presents of the second portion of the generated script. In one example, the presentation of the first portion of the generated script by the synthetic character caused by Step 830 may be presented over a background including the at least part of the first image data, and/or the presentation of the second portion of the generated script by the synthetic character caused by Step 830 may be presented over a background including the at least part of the second image data, for example as described above.

In some examples, images of the synthetic character visually indicating a region (for example, with a hand, with a figure, with a gesture, etc.) may be used in the generation of the visualization of the synthetic character, and may be stitched over an image to generate the synthetic character visually indicating a selected region of the image (such as a region of a depiction of an object in the image, a region corresponding to a construction error, and so forth). For example, in the context of method 800, the first portion of the script generated by Step 820 may be related to a first object at the first section of the construction site, the second portion of the script generated by Step 820 may be related to a second object at the second section of the construction site, and the generated visual representation of the synthetic character presenting the generated script may include a visual representation of the synthetic character visually indicating a depiction of the first object in the at least part of the first image data while presenting the first portion of the generated script, and/or a visual representation of the synthetic character visually indicating a depiction of the second object in the at least part of the second image data while presenting the second portion of the generated script. In another example, in the context of method 800, the first portion of the script generated by Step 820 may be related to a construction error at the first section of the construction site, the second portion of the script generated by Step 820 may be related to a construction error at the second section of the construction site, and the generated visual representation of the synthetic character presenting the script generated by Step 820 may include a visual representation of the synthetic character visually indicating a location in the at least part of the first image data associated with the construction error at the first section of the construction site while presenting the first portion of the generated script, and/or a visual representation of the synthetic character visually indicating a location in the at least part of the second image data associated with the construction error at the second section of the construction site while presenting the second portion of the generated script. In yet another example, in the context of method 900, the script generated by Step 920 may be related to a construction error visible in the first image data and fixed before the second time period, the first portion of the script generated by Step 920 may relate to the construction error, the second portion of the script generated by Step 920 may relate to the fix of the construction error, and the generated visual representation of the synthetic character presenting the generated script may include a visual representation of the synthetic character visually indicating a location in the at least part of the first image data associated with the construction error, for example while presenting the first portion of the script generated by Step 920. In an additional example, in the context of method 900, the script generated by Step 920 may be related to a modification to an object in the construction site between the first time period and the second time period, and the generated visual representation of the synthetic character presenting the generated script may include a visual representation of the synthetic character visually indicating a location corresponding to the object in the at least part of the first image data (for example, while presenting the first portion of the script generated by Step 920) and a visual representation of the synthetic character visually indicating the object in the at least part of the second image data (for example, while presenting the second portion of the script generated by Step 920). In yet another example, in the context of method 900, the script generated by Step 920 may be related to an object installed in the construction site between the first time period and the second time period (such as object 722 of image 720), and the generated visual representation of the synthetic character presenting the generated script may include a visual representation of the synthetic character visually indicating the installed object in the at least part of the second image data, for example while presenting the second portion of the script generated by Step 920. For example, the generated visual representation of the synthetic character presenting the generated script may include a visual representation of the synthetic character visually indicating a location where the object is about to be installed in the at least part of the first image data, for example while presenting the first portion of the script generated by Step 920.

In the context of method 800, in some examples, the generated visual representation of the synthetic character presenting the script generated by Step 820 may include a depiction of the synthetic character walking from the first section of the construction site to the second section of the construction site. For example, a depiction of a walking synthetic character may be stitched over a video in which the camera moves from the first section of the construction site to the second section of the construction site. For example, the depiction of the synthetic character walking from the first section of the construction site to the second section of the construction site may be part of a video including the presentation of the first portion of the generated script by the synthetic character and/or the presentation of the second portion of the generated script by the synthetic character, and may be positioned after the presentation of the first portion of the generated script by the synthetic character and/or before the presentation of the second portion of the generated script by the synthetic character.

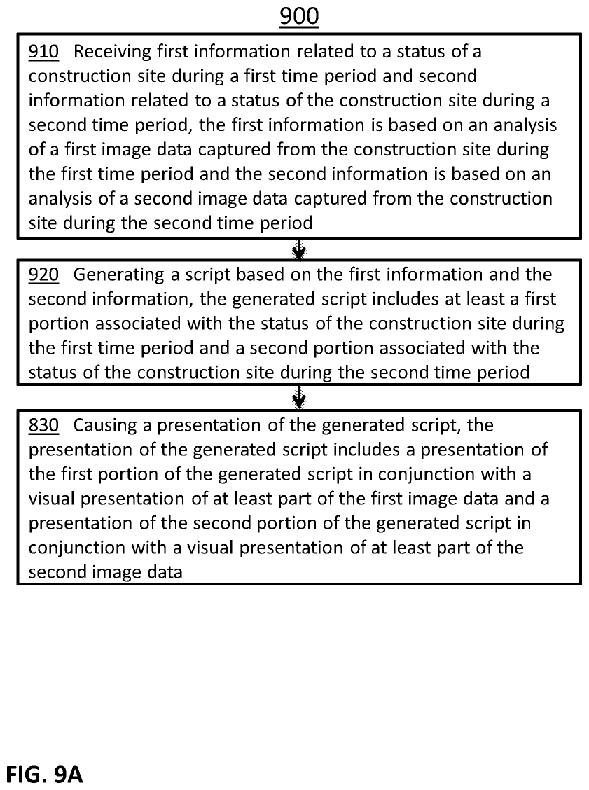

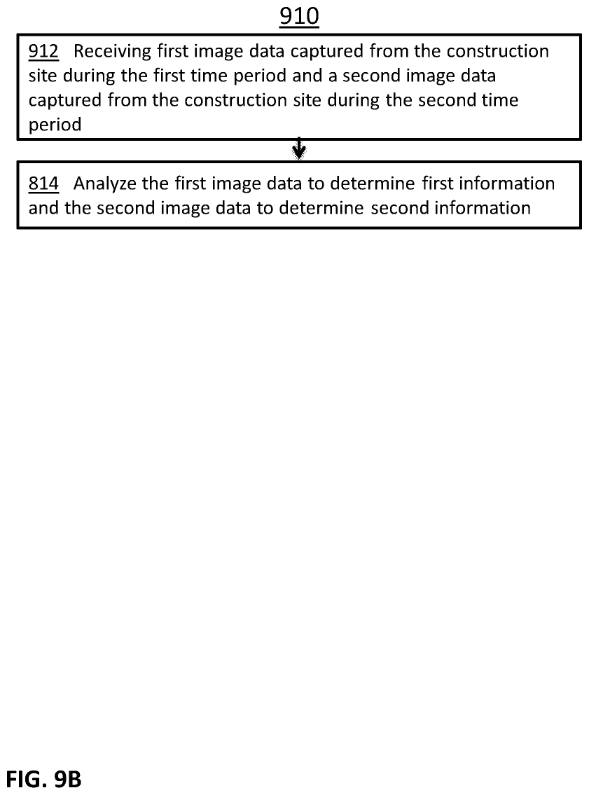

FIG. 9A illustrates an example method 900 for generating and presenting scripts related to different time periods in construction sites. In this example, method 900 may comprise: receiving first information related to a status of a construction site during a first time period and second information related to a status of the construction site during a second time period (Step 910), the first information may be based on an analysis of a first image data captured from the construction site during the first time period and the second information may be based on an analysis of a second image data captured from the construction site during the second time period; generating a script based on the first information and the second information (Step 920), the generated script may include at least a first portion associated with the status of the construction site during the first time period and/or a second portion associated with the status of the construction site during the second time period; and causing a presentation of the generated script (Step 830), the presentation of the generated script may include a presentation of the first portion of the generated script in conjunction with a visual presentation of at least part of the first image data and a presentation of the second portion of the generated script in conjunction with a visual presentation of at least part of the second image data. For example, the second time period may differ from the first time period. In one example, there may be no overlap between the first time period and the second time period. In another example, there may be some overlap between the first time period and the second time period. For example, there may be at least a selected elapsed time between the first time period and the second time period (for example, at least an hour, at least a day, at least a week, and so forth). In some implementations, method 900 may comprise one or more additional steps, while some of the steps listed above may be modified or excluded. For example, Step 830 may be excluded from method 900. In some implementations, one or more steps illustrated in FIG. 9A may be executed in a different order and/or one or more groups of steps may be executed simultaneously and vice versa.

In some embodiments, Step 910 may comprise receiving first information related to a status of a construction site during a first time period and/or second information related to a status of the construction site during a second time period. The second time period may differ from the first time period. The first information may be based on an analysis of a first image data captured from the construction site during the first time period, and the second information may be based on an analysis of a second image data captured from the construction site during the second time period. For example, Step 910 may read the first information and/or the second information from memory, for example from memory units 210, shared memory modules 410, memory 600, and so forth. In another example, Step 910 may receive the first information and/or the second information from an external device, from another process, and so forth. In another example, Step 910 may receive the first information and/or the second information using one or more communication devices, such as communication modules 230, internal communication modules 440, external communication modules 450, and so forth. In some examples, the first information may include values of pixels from the first image data, information based on the values of pixels from the first image data, and so forth. In some examples, the second information may include values of pixels from the second image data, information based on the values of pixels from the second image data, and so forth. In some examples, the first image data may include at least one image, and the first information may include at least one of a portion of the at least one image, a transformation of the portion, information based on an analysis of the portion, and so forth. In some examples, the second image data may include at least one image, and the second information may include at least one of a portion of the at least one image, a transformation of the portion, information based on an analysis of the portion, and so forth. In some examples, Step 910 may generate the first information based on an analysis of the first image data and/or may generate the second information based on an analysis of the second image data. One possible implementation of Step 910 is illustrated in FIG. 9B.

FIG. 9B illustrates a non-limiting example of a possible implementation of Step 910. In this example, Step 910 may comprise: receiving first image data captured from the construction site during the first time period and a second image data captured from the construction site during the second time period (Step 912); and analyzing the first image data to determine first information and the second image data to determine second information (Step 814). In some implementations, Step 814 may be executed after and/or simultaneously with Step 912.

In some embodiments, Step 912 may comprise receiving the first image data and/or the second image data. For example, the first image data may include image data captured from the construction site during the first time period and/or the second image data may include image data captured from the construction site during the second time period. In one example, Step 912 may use Module 655 to receive the first image data and/or to receive the second image data. In one example, the first image data received by Step 912 may include and/or be based on image 700, and the second image data received by Step 912 may include and/or be based on image 720.

In some embodiments, Step 920 may comprise generating a script based on the first information received by Step 910 and/or the second information received by Step 910. The generated script may include at least a first portion associated with the status of the construction site during the first time period and/or a second portion associated with the status of the construction site during the second time period. In some examples, Step 920 may analyze the first information received by Step 910 and/or the second information received by Step 910 to generate the script. For example, a machine learning model may be trained using training examples to generate scripts from information, and Step 920 may use the trained machine learning model, the first information received by Step 910 and/or the second information received by Step 910 to generate the script. One example of such training example may include sample information, together with a corresponding desired script. In another example, in response to a first combination of first information and second information, Step 920 may generate a first script, and in response to a second combination of first information and second information, Step 920 may generate a second script, the second script may differ from the first script. In yet another example, the first portion of the script may include information included and/or indicated by in the first information (such as a quantity, a type of object, a status, and so forth, for example a quantity, a type or a status associated with the construction site during the first time period) and the second portion of the script may include information included and/or indicated by in the second information (such as a quantity, a type of object, a status, and so forth, for example a quantity, a type or a status associated with the construction site during the second time period).

In some examples, Step 920 may further base the generation of the script on at least one of a construction plan associated with the construction site, a project schedule associated with the construction site, a progress record associated with the construction site and a financial record associated with the construction site. For example, Step 920 may base the generation of the script on a first element of the construction plan corresponding to construction site during the first time period and/or on a second element of the construction plan corresponding to the construction site during the second time period. In this example, the first portion of the script may include information included and/or indicated by in the first information and information based on the first element of the construction plan, and/or the second portion of the script may include information included and/or indicated by in the second information and information based on the second element of the construction plan. In another example, Step 920 may base the generation of the script on a first task in the project schedule corresponding to the construction site during the first time period and/or on a second task in the project schedule corresponding to the construction site during the second time period. In this example, the first portion of the script may include information included and/or indicated by in the first information and information based on the first task of the project schedule, and/or the second portion of the script may include information included and/or indicated by in the second information and information based on the second task of the project schedule. In yet another example, Step 920 may base the generation of the script on a first progress indicator in the progress record corresponding to a progress in the construction site during the first time period and/or on a second progress indicator in the project schedule corresponding to a progress in the construction site during the second time period. In this example, the first portion of the script may include information included and/or indicated by in the first information and information based on the first progress indicator, and/or the second portion of the script may include information included and/or indicated by in the second information and information based on the second progress indicator. In an additional example, Step 920 may base the generation of the script on a first financial transaction in the financial record corresponding to the construction site during the first time period and/or on a second financial transaction in the financial record corresponding to the construction site during the second time period. In this example, the first portion of the script may include information included and/or indicated by in the first information and information based on the first financial transaction, and/or the second portion of the script may include information included and/or indicated by in the second information and information based on the second financial transaction.

In some examples, the script generated by Step 920 may be related to a construction error visible in the first image data and fixed before the second time period, the first portion of the script generated by Step 920 may relate to the construction error and the second portion of the script generated by Step 920 may relate to the fix of the construction error. For example, Step 920 may use the first information and/or a construction plan associated with the construction site to generate an indication of the construction error and include it in the first portion of the script. For example, the indication of the construction error may be an indication of a discrepancy between the construction site during the first time period and the construction plan. In some examples, the script generated by Step 920 may be related to a usage of materials at the construction site between the first time period and the second time period. For example, the script generated by Step 920 may be indicative of a type of the materials used, may be indicative of a quantity of the materials used, may be indicative of a type of usage, may be indicative of a location where the materials were used in the construction site, may be indicative of a prospective usage of materials in the construction site, and so forth. In one example, Step 920 may compare the first information with the second information (and/or may compare the first image data with the second image data) to determine the usage of materials at the construction site between the first time period and the second time period. In another example, Step 920 may analyze at least one of a progress record and a financial record corresponding to the construction site to determine the usage of materials at the construction site between the first time period and the second time period. In some examples, the script generated by Step 920 may be related to a material used at the construction site between the first time period and the second time period. In one example, Step 920 may compare the first information with the second information (and/or may compare the first image data with the second image data) to determine the material used at the construction site between the first time period and the second time period. In another example, Step 920 may analyze at least one of a progress record and a financial record corresponding to the construction site to determine the material used at the construction site between the first time period and the second time period. In some examples, the script generated by Step 920 may be related to a work performed at the construction site between the first time period and the second time period. For example, the first portion of the script generated by Step 920 may be indicative that the work had not started by the first time period and the second portion of the script generated by Step 920 may be indicative that the work had finished by the second time period. In one example, Step 920 may compare the first information with the second information (and/or may compare the first image data with the second image data) and/or a progress record associated with the construction site to determine that the work was performed at the construction site between the first time period and the second time period. In some examples, the script generated by Step 920 may be related to an issue resolved at the construction site between the first time period and the second time period. Some non-limiting examples of such issue may include a safety issue, a quality issue, a scheduling issue, and so forth. Some non-limiting examples of such quality issues may include a usage of a low quality element, a usage of an incompatible element, a problem in an installation of an element, and so forth. Some non-limiting examples of such safety issues may include a failure to use safety equipment, a failure to follow safety guidelines, and so forth. For example, the first portion of the script generated by Step 920 may include an indication of the issue at the first time period and the second portion of the script generated by Step 920 may include an indication that the issue was resolved by the second time period. In one example, Step 920 may analyze the first information to determine the existence of the issue at the first time period, and may analyze the second information to determine that the issue was resolved by the second time period. In some examples, the script generated by Step 920 may be related to an issue arising at the construction site between the first time period and the second time period (such as a safety issue, a quality issue, a scheduling issue, and so forth). For example, the first portion of the script generated by Step 920 may include an indication of the issue did not exist at the first time period and the second portion of the script generated by Step 920 may include an indication that the issue has arisen by the second time period. In one example, Step 920 may analyze the first information to determine the issue did not exist at the first time period, and may analyze the second information to determine that the issue has arisen by the second time period. In some examples, the script generated by Step 920 may be related to a delay arising at the construction site between the first time period and the second time period. For example, the first portion of the script generated by Step 920 may include an indication of there was no delay or that there is a first amount of delay at the first time period, and the second portion of the script generated by Step 920 may include an indication that the delay has arisen by the second time period (for example, that the delay exists at the second time period or that the amount of delay increased by the second time period). For example, Step 920 may use the first information together with a project schedule associated with the construction site and/or a progress record associated with the construction site to determine that there is no delay or that there is a first amount of delay at the first time period, and may use the second information together with a project schedule associated with the construction site and/or a progress record associated with the construction site to determine that the delay exists at the second time period or that the amount of delay increased by the second time period.

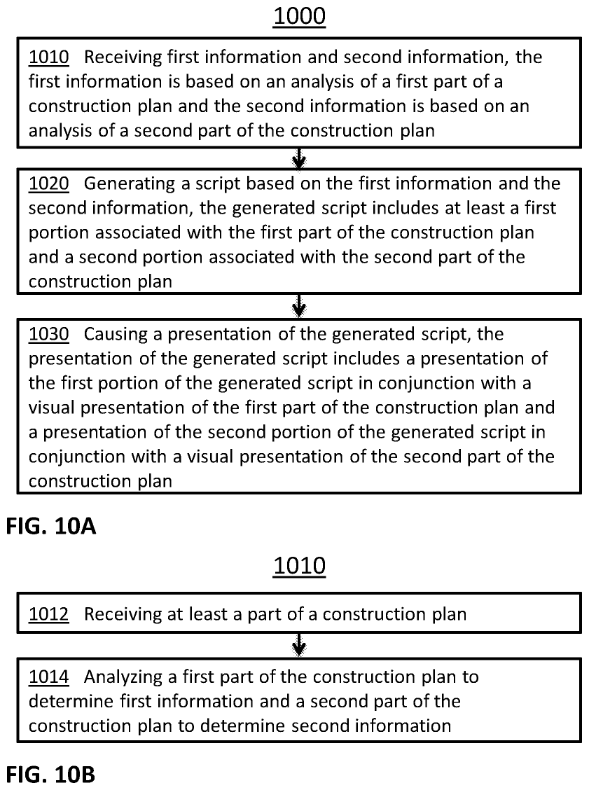

FIG. 10A illustrates an example method 1000 for generating and presenting scripts related to different portions of construction plans. In this example, method 1000 may comprise: receiving first information and second information (Step 1010), the first information may be based on an analysis of a first part of a construction plan and the second information may be based on an analysis of a second part of the construction plan; generating a script based on the first information and the second information (Step 1020), the generated script may include at least a first portion associated with the first part of the construction plan and a second portion associated with the second part of the construction plan; and causing a presentation of the generated script (Step 1030), the presentation of the generated script may include a presentation of the first portion of the generated script in conjunction with a visual presentation of the first part of the construction plan and/or a presentation of the second portion of the generated script in conjunction with a visual presentation of the second part of the construction plan. For example, the second part of the construction plan may differ from the first part of the construction plan. In one example, there may be no overlap between the first part of the construction plan and the second part of the construction plan. In another example, there may be some overlap between the first part of the construction plan and the second part of the construction plan. In some implementations, method 1000 may comprise one or more additional steps, while some of the steps listed above may be modified or excluded. For example, Step 1030 may be excluded from method 1000. In some implementations, one or more steps illustrated in FIG. 10A may be executed in a different order and/or one or more groups of steps may be executed simultaneously and vice versa.

In some embodiments, the first part of the construction plan may correspond to a first section of a construction site, and/or the second part of the construction plan may correspond to a second section of the construction site, the second section of the construction site may differ from the first section of the construction site. In one example, the first information may be or include information on a status of the first section of the construction site and/or the second information may be or include information on a status of the second section of the construction site. In some embodiments, the first part of the construction plan may correspond to a first room, and/or the second part of the construction plan may correspond to a second room, the second room may differ from the first room. In some embodiments, the first part of the construction plan may correspond to a first wall, and/or the second part of the construction plan may correspond to a second wall, the second wall may differ from the first wall. In some embodiments, the first part of the construction plan may correspond to a first story, and/or the second part of the construction plan may correspond to a second story, the second story may differ from the first story.

In some embodiments, Step 1010 may comprise receiving first information and second information. The first information may be based on an analysis of a first part of a construction plan and/or the second information may be based on an analysis of a second part of the construction plan. The second part of the construction plan may differ from the first part of the construction plan. For example, Step 1010 may read the first information and/or the second information from memory, for example from memory units 210, shared memory modules 410, memory 600, and so forth. In another example, Step 1010 may receive the first information and/or the second information from an external device, from another process, and so forth. In another example, Step 1010 may receive the first information and/or the second information using one or more communication devices, such as communication modules 230, internal communication modules 440, external communication modules 450, and so forth. In some examples, the first information may include at least part of the first part of a construction plan, information based on the first part of a construction plan, and so forth. In some examples, the second information may include at least part of the second part of a construction plan, information based on the at least part of the second part of a construction plan, and so forth. In some examples, the first part of a construction plan may correspond to at least part of at least one IFC file, and the first information may include at least one element of the at least part of at least one IFC file and/or information based on the at least one element. In some examples, the second part of a construction plan may correspond to at least part of at least one IFC file, and the first information may include at least one element of the at least part of at least one IFC file and/or information based on the at least one element. In some examples, Step 1010 may generate the first information based on an analysis of the first part of a construction plan and/or may generate the second information based on an analysis of the second part of a construction plan. One possible implementation of Step 1010 is illustrated in FIG. 10B.

FIG. 10B illustrates a non-limiting example of a possible implementation of Step 1010. In this example, Step 1010 may comprise: receiving at least a part of a construction plan (Step 1012); and analyzing a first part of the construction plan to determine first information and a second part of the construction plan to determine second information (Step 1014). In some implementations, Step 1014 may be executed after and/or simultaneously with Step 1012.

In some embodiments, Step 1012 may comprise receiving the first part of the construction plan and/or the second part of the construction plan. For example, Step 1012 may receive a construction plan including the first part and the second part. In another example, Step 1012 may receive a floor plan including the first part of the construction plan and/or the second part of the construction plan. In yet another example, Step 1012 may receive one or more BIM models including the first part of the construction plan and/or the second part of the construction plan. In an additional example, Step 1012 may receive one or more IFC files including the first part of the construction plan and/or the second part of the construction plan. In one example, Step 1012 may access construction plans 610 to obtain the construction plan. One non-limiting example of a construction plan received by Step 1012 may include construction plan 760.

In some examples, Step 1012 may read the first part and/or the second part of the construction plan from memory, for example from memory units 210, shared memory modules 410, memory 600, and so forth. In another example, Step 1012 may receive the first part and/or the second part of the construction plan from an external device, from another process, and so forth. In yet another example, Step 1012 may receive the first part and/or the second part of the construction plan using one or more communication devices, such as communication modules 230, internal communication modules 440, external communication modules 450, and so forth. In an additional example, Step 1012 may generate the first part and/or the second part of the construction plan.

In some embodiments, Step 1014 may comprise analyzing the first part of the construction plan received by Step 1012 to determine the first information and/or analyzing the second part of the construction plan received by Step 1012 to determine the second information. For example, a machine learning model may be trained using training examples to determine information from construction plans, and Step 1014 may use the trained machine learning model to analyze the first part of the construction plan received by Step 1012 to determine the first information and/or to analyze the second part of the construction plan received by Step 1012 to determine the second information. One example of such training data may include a sample portion of a construction plan, together with a sample of desired information corresponding to the sample portion of the construction plan.

In some embodiments, the first part of the construction plan may correspond to a first section of a construction site, and/or the second part of the construction plan may correspond to a second section of the construction site, as described above. In some examples, the first information received by Step 1010 may be further based on an analysis of first image data captured from the first section of the construction site and/or the second information received by Step 1010 may be further based on an analysis of second image data captured from the first section of the construction site, for example as described above in relation to method 800. In one example, the first image may be compared to the first part of the construction plan to determine the first information, and/or the second image may be compared to the second part of the construction plan to determine the second information. In one example, the first image data may be received (for example using Step 812), and the first image data may be analyzed (for example, together with the first part of the construction plan) to generate the first information, for example as described above in relation to method 800. For example, a convolution of at least part of the first image data may be calculated, and the calculated convolution may be used (for example, together with the first part of the construction plan) to generate the first information, for example as described above in relation to method 800. In one example, the second image data may be received (for example using Step 812), and the second image data may be analyzed (for example, together with the second part of the construction plan) to generate the second information, for example as described above in relation to method 800. For example, a convolution of at least part of the second image data may be calculated, and the calculated convolution may be used (for example, together with the second part of the construction plan) to generate the second information, for example as described above in relation to method 800.

In some embodiments, Step 1020 may comprise generating a script based on the first information received by Step 1010 and/or the second information received by Step 1010. The generated script may include at least a first portion associated with the first part of the construction plan and/or a second portion associated with the second part of the construction plan. In some examples, Step 1020 may analyze the first information received by Step 1010 and/or the second information received by Step 1010 to generate the script. For example, a machine learning model may be trained using training examples to generate scripts from information, and Step 1020 may use the trained machine learning model, the first information received by Step 1010 and/or the second information received by Step 1010 to generate the script. One example of such training example may include sample information, together with a corresponding desired script. In another example, in response to a first combination of first information and second information, Step 1020 may generate a first script, and in response to a second combination of first information and second information, Step 1020 may generate a second script, the second script may differ from the first script. In yet another example, the first portion of the script may include information included and/or indicated by in the first information received by Step 1010 (such as a quantity, a type of an element, a location of an element, and so forth, for example a quantity, a type, a location included in and/or indicated by the first part of the construction plan) and the second portion of the script may include information included and/or indicated by in the second information received by Step 1010 (such as a quantity, a type of an element, a location of an element, and so forth, for example a quantity, a type, a location included in and/or indicated by the first part of the construction plan). In some examples, Step 1020 may base the generation of the script on a first element of the first part of the construction plan and/or on a second element of the second part of the construction plan. For example, the first portion of the script may include information included and/or indicated by in the first information and information based on the first element, and/or the second portion of the script may include information included and/or indicated by in the second information and information based on the second element.

In some embodiments, Step 1020 may further base the generation of the script on at least one of a project schedule associated with the construction plan, a progress record associated with the construction plan and a financial record associated with the construction plan. For example, Step 1020 may base the generation of the script on a first task in the project schedule corresponding to a section of the construction site corresponding to the first part of the construction plan and/or on a second task in the project schedule corresponding to a section of the construction site corresponding to the second part of the construction plan. In this example, the first portion of the script may include information included and/or indicated by in the first information and information based on the first task of the project schedule, and/or the second portion of the script may include information included and/or indicated by in the second information and information based on the second task of the project schedule. In another example, 1020 may base the generation of the script on a first progress indicator in the progress record corresponding to a progress in a section of the construction site corresponding to the first part of the construction plan and/or on a second progress indicator in the project schedule corresponding to a progress in a section of the construction site corresponding to the second part of the construction plan. In this example, the first portion of the script may include information included and/or indicated by in the first information and information based on the first progress indicator, and/or the second portion of the script may include information included and/or indicated by in the second information and information based on the second progress indicator. In an additional example, Step 1020 may base the generation of the script on a first financial transaction in the financial record corresponding to a section of the construction site corresponding to the second part of the construction plan and/or on a second financial transaction in the financial record corresponding to a section of the construction site corresponding to the second part of the construction plan. In this example, the first portion of the script may include information included and/or indicated by in the first information and information based on the first financial transaction, and/or the second portion of the script may include information included and/or indicated by in the second information and information based on the second financial transaction.

In some embodiments, the first part of the construction plan may correspond to a first section of a construction site, and/or the second part of the construction plan may correspond to a second section of the construction site, as described above. In some examples, the first portion of the script generated by Step 1020 may be related to a delay at the first section of the construction site, and/or the second portion of the script generated by Step 1020 may be related to a delay at the second section of the construction site. For example, a delay in a section of the construction site may be determined by comparing image data captured from the section of the construction site to a part of the project schedule corresponding to the construction site, may be determined by comparing a progress record corresponding to the construction site to a project schedule corresponding to the construction site, and so forth. In some examples, the first portion of the script generated by Step 1020 may be related to a completion of work at the first section of the construction site, and/or the second portion of the script generated by Step 1020 may be related to a completion of work at the second section of the construction site. For example, a completion of work (such as a particular construction task, all construction tasks of a particular type, etc.) at a section of the construction site may be determined by analyzing image data captured from the section of the construction site, by analyzing a progress record corresponding to the construction site, by analyzing a project schedule corresponding to the construction site, and so forth. In some examples, the first portion of the script generated by Step 1020 may be related to a construction error at the first section of the construction site, and wherein the second portion of the script generated by Step 1020 may be related to a construction error at the second section of the construction site. For example, a construction error at a section of the construction site may be determined by analyzing image data captured from the section of the construction site, by comparing the image date to a part of the construction plan corresponding to the section of the construction site (for example, to identify a discrepancy between the construction site and the construction plan), and so forth. In some examples, the first portion of the script generated by Step 1020 may be related to a quality issue at the first section of the construction site, and/or the second portion of the script generated by Step 1020 may be related to a quality issue at the second section of the construction site. Some non-limiting examples of such quality issues may include a usage of a low quality element, a usage of an incompatible element, a problem in an installation of an element, and so forth. For example, a quality issue at a section of the construction site may be determined by analyzing image data captured from the section of the construction site, by comparing the image date to a part of the construction plan corresponding to the section of the construction site (for example, to identify a discrepancy between the construction site and the construction plan), and so forth. In some examples, the first portion of the script generated by Step 1020 may be related to a safety issue at the first section of the construction site, and/or the second portion of the script generated by Step 1020 may be related to a safety issue at the second section of the construction site. Some non-limiting examples of such safety issues may include a failure to use safety equipment, a failure to follow safety guidelines, and so forth. For example, a safety issue at a section of the construction site may be determined by analyzing image data captured from the section of the construction site, by analyzing a part of the construction plan corresponding to the section of the construction site, and so forth. In some examples, the first portion of the script generated by Step 1020 may be related to a usage of materials at the first section of the construction site, and/or the second portion of the script generated by Step 1020 may be related to a usage of materials at the second section of the construction site. For example, the script generated by Step 1020 may be indicative of a type of the materials used in the corresponding section of the construction site, may be indicative of a quantity of the materials used in the corresponding section of the construction site, may be indicative of a type of usage in the corresponding section of the construction site, may be indicative of a prospective usage of materials in the corresponding section of the construction site, and so forth. For example, a usage of materials at a section of the construction site may be determined by analyzing image data captured from the section of the construction site, by analyzing a part of the construction plan corresponding to the section of the construction site, by analyzing a progress record corresponding to the section of the construction site, by analyzing a financial record corresponding to the section of the construction site, and so forth. In some examples, the first portion of the script generated by Step 1020 may be related to a material used at the first section of the construction site, and/or the second portion of the script generated by Step 1020 may be related to a material used at the second section of the construction site. In some examples, the first portion of the script generated by Step 1020 may be related to a prospective construction work at the first section of the construction site, and/or the second portion of the script generated by Step 1020 may be related to a prospective construction work at the second section of the construction site. For example, the prospective construction work at a section of the construction site may be determined by analyzing image data captured from the section of the construction site, by analyzing a part of the construction plan corresponding to the section of the construction site, by analyzing a progress record corresponding to the section of the construction site, by analyzing a financial record corresponding to the section of the construction site, and so forth. In some examples, the first portion of the script generated by Step 1020 may be related to a readiness for a prospective construction work at the first section of the construction site, and/or the second portion of the script generated by Step 1020 may be related to an unreadiness for the prospective construction work at the second section of the construction site. For example, readiness and/or unreadiness for a prospective construction work at a section of the construction site may be determined by analyzing image data captured from the section of the construction site, by analyzing a part of the construction plan corresponding to the section of the construction site, by analyzing a progress record corresponding to the section of the construction site, by analyzing a financial record corresponding to the section of the construction site, and so forth.

In some embodiments, Step 1030 may cause a presentation of the script generated by Step 1020. The presentation of the script generated by Step 1020 may include a presentation of the first portion of the script generated by Step 1020 in conjunction with a visual presentation of the first part of the construction plan and/or a presentation of the second portion of the script generated by Step 1020 in conjunction with a visual presentation of the second part of the construction plan. In some examples, the presentation of the first portion of the script generated by Step 1020 and/or the presentation of the second portion of the script generated by Step 1020 may be audible. For example, the presentation of the script generated by Step 1020 may include a video with audible presentation of the first portion of the script generated by Step 1020 in conjunction with frames including a visual presentation of at least part of the first part of the construction plan and with audible presentation of the second portion of the generated script in conjunction with frames including a visual presentation of at least part of the second part of the construction plan. In one example, the audible presentation of the generated script may be generated using a text-to-speech algorithm. In some examples, the presentation of the first portion of the script generated by Step 1020 may include a presentation of the first portion of the script generated by Step 1020 in a textual form in conjunction with the visual presentation of the first part of the construction plan, and/or the presentation of the second portion of the script generated by Step 1020 may include a presentation of the second portion of the script generated by Step 1020 in textual form in conjunction with the visual presentation of the second part of the construction plan. For example, the presentation of the first portion of the script generated by Step 1020 may include a presentation of the first portion of the generated script in subtitles in conjunction with the visual presentation of the first part of the construction plan, and/or the presentation of the second portion of the script generated by Step 1020 may include a presentation of the second portion of the generated script in subtitles in conjunction with the visual presentation of the second part of the construction plan.

In some examples, Step 1030 may cause an external device to present the presentation of the script generated by Step 1020, for example by transmitting instructions and/or data to the external device. In some examples, Step 1030 may store a media file of the presentation of the script generated by Step 1020 in memory, for example in a format (such as one or more image files, a video file, etc.) enabling another process and/or another device to present the presentation of the script. In some examples, Step 1030 may cause the presentation of the script generated by Step 1020 on a display screen, in a virtual reality system, in an augmented reality system, and so forth.

In some embodiments, Step 1030 may use the script generated by Step 1020 to generate a visual representation of a synthetic character presenting the script generated by Step 1020, the presentation of the script generated by Step 1020 by the synthetic character may include a presentation of the first portion of the generated script by the synthetic character in conjunction with the visual presentation of the first part of the construction plan and/or a presentation of the second portion of the generated script by the synthetic character in conjunction with the visual presentation of the second part of the construction plan. In some examples, the synthetic character may be at least one of a synthetic character of a civil engineer, a synthetic character of financial accountant, a synthetic character of an architect, a synthetic character of a real-estate developer and a synthetic character of an operations manager. In some examples, the synthetic character may be selected (for example, from a plurality of alternative synthetic characters) based on a characteristic of a prospective viewer. In some examples, GAN may be used to train an artificial neural network to generate, from scripts, visual presentations of synthetic characters presenting scripts, and Step 1030 may use the trained artificial neural network to generate, from the script generated by Step 1020, the visual representation of the synthetic character presenting the script generated by Step 1020. In some examples, Step 1030 may generate a video visualization of the synthetic character presenting the script generated by Step 1020 by using an image of the synthetic character and modifying the lips region of the face of the synthetic character to mimic lips movement (for example, using a lips movement generation algorithm) corresponding to the synthetic character saying the words of the scripts at the same time where audible presentation of the words is presented (for example, audible presentation generated using a text-to-speech algorithm). In some examples, Step 1030 may generate a visualization of the synthetic character presenting the script generated by Step 1020 by adding speech bubbles corresponding to the script to images of the synthetic character. In some examples, Step 1030 may stitch the visual representation of the synthetic character presenting the script generated by Step 1020 on different backgrounds, such as the visual presentation of the at least part of the first part of the construction plan and/or the visual presentation of the at least part of the second part of the construction plan. Different backgrounds may be used while the synthetic character presents different portions of the scripts, for example using a background including at least part of the first part of the construction plan when the synthetic character presents of the first portion of the generated script and/or using a background including at least part of the second part of the construction plan when the synthetic character presents of the second portion of the generated script. In some examples, Step 1030 may present the visual representation of the synthetic character presenting the script generated by Step 1020 next to different visuals, such as the visual presentation of the at least part of the first part of the construction plan and/or the visual presentation of the at least part of the second part of the construction plan. Different visuals may be used while the synthetic character presents different portions of the scripts, for example presenting a visual including at least part of the first part of the construction plan next to the synthetic character presenting of the first portion of the generated script and/or using a visual including at least part of the second part of the construction plan next to the synthetic character presents of the second portion of the generated script. In one example, the presentation of the first portion of the generated script by the synthetic character caused by Step 1030 may be presented over a background including the at least part of the first part of the construction plan, and/or the presentation of the second portion of the generated script by the synthetic character caused by Step 1030 may be presented over a background including the at least part of the second part of the construction plan, for example as described above.

In some examples, images of the synthetic character visually indicating a region (for example, with a hand, with a figure, with a gesture, etc.) may be used in the generation of the visualization of the synthetic character, and may be stitched over an image to generate the synthetic character visually indicating a selected region of the image (such as a region of a depiction of an object in the image, a region corresponding to a construction error, and so forth). For example, the first portion of the generated script may be related to a first element of the construction plan, the second portion of the generated script may be related to a second element of the construction plan, and the generated visual representation of the synthetic character presenting the generated script may include a visual representation of the synthetic character visually indicating a location in the first part of the construction plan corresponding to the first element while presenting the first portion of the generated script, and/or a visual representation of the synthetic character visually indicating a location in the second part of the construction plan corresponding to the second element while presenting the second portion of the generated script. In another example, the first part of the construction plan may correspond to a first section of a construction site and/or the second part of the construction plan may correspond to a second section of the construction site, the first portion of the generated script may be related to a construction error at the first section of the construction site, the second portion of the generated script may be related to a construction error at the second section of the construction site, and the generated visual representation of the synthetic character presenting the generated script may include a visual representation of the synthetic character visually indicating a location in the first part of the construction plan associated with the construction error at the first section of the construction site while presenting the first portion of the generated script, and/or a visual representation of the synthetic character visually indicating a location in the second part of the construction plan associated with the construction error at the second section of the construction site while presenting the second portion of the generated script.

What is claimed is:

1. A non-transitory computer readable medium storing data and computer implementable instructions for carrying out a method for generating and presenting scripts related to different sections of construction sites, the method comprising:
receiving first information and second information, the first information is based on an analysis of a first image data captured from a first section of a construction site and the second information is based on an analysis of a second image data captured from a second section of the construction site, the second section of the construction site differs from the first section of the construction site;
generating a script based on the first information and the second information, the generated script includes at least a first portion associated with the first section of the construction site and a second portion associated with the second section of the construction site; and
causing a presentation of the generated script, the presentation of the generated script includes a presentation of the first portion of the generated script in conjunction with a visual presentation of at least part of the first image data and a presentation of the second portion of the generated script in conjunction with a visual presentation of at least part of the second image data.

2. The non-transitory computer readable medium of claim 1, wherein the generation of the script is further based on at least one of a construction plan associated with the construction site, a project schedule associated with the construction site, a progress record associated with the construction site and a financial record associated with the construction site.

3. The non-transitory computer readable medium of claim 1, wherein the presentation of the first portion of the generated script and the presentation of the second portion of the generated script are audible.

4. The non-transitory computer readable medium of claim 1, wherein the presentation of the first portion of the generated script includes a presentation of the first portion of the generated script in a textual form in conjunction with the visual presentation of the at least part of the first image data, and wherein the presentation of the second portion of the generated script includes a presentation of the second portion of the generated script in textual form in conjunction with the visual presentation of the at least part of the second image data.

5. The non-transitory computer readable medium of claim 1, wherein the first portion of the generated script is indicative of a delay at the first section of the construction site, and wherein the second portion of the generated script is indicative of a delay at the second section of the construction site.

6. The non-transitory computer readable medium of claim 1, wherein the first portion of the generated script is indicative of a completion of work at the first section of the construction site, and wherein the second portion of the generated script is indicative of a completion of work at the second section of the construction site.

7. The non-transitory computer readable medium of claim 1, wherein the first portion of the generated script is indicative of a construction error at the first section of the construction site, and wherein the second portion of the generated script is indicative of a construction error at the second section of the construction site.

8. The non-transitory computer readable medium of claim 1, wherein the first portion of the generated script is indicative of a quality issue at the first section of the construction site, and wherein the second portion of the generated script is indicative of a quality issue at the second section of the construction site.

9. The non-transitory computer readable medium of claim 1, wherein the first portion of the generated script is indicative of a safety issue at the first section of the construction site, and wherein the second portion of the generated script is indicative of a safety issue at the second section of the construction site.

10. The non-transitory computer readable medium of claim 1, wherein the first portion of the generated script is indicative of a usage of materials at the first section of the construction site, and wherein the second portion of the generated script is indicative of a usage of materials at the second section of the construction site.

11. The non-transitory computer readable medium of claim 1, wherein the first portion of the generated script is indicative of a material used at the first section of the construction site, and wherein the second portion of the generated script is indicative of a material used at the second section of the construction site.

12. The non-transitory computer readable medium of claim 1, wherein the first portion of the generated script is indicative of a first prospective construction work at the first section of the construction site, and wherein the second portion of the generated script is indicative of a second prospective construction work at the second section of the construction site.

13. The non-transitory computer readable medium of claim 1, wherein the first portion of the generated script is indicative of a readiness for a prospective construction work at the first section of the construction site, and wherein the second portion of the generated script is indicative of a unreadiness for the prospective construction work at the second section of the construction site.

14. The non-transitory computer readable medium of claim 1, wherein the method further comprises:
using the generated script to generate a visual representation of a synthetic character presenting the generated script, the presentation of the generated script by the synthetic character includes a presentation of the first portion of the generated script by the synthetic character in conjunction with the visual presentation of the at least part of the first image data and a presentation of the second portion of the generated script by the synthetic character in conjunction with the visual presentation of the at least part of the second image data.

15. The non-transitory computer readable medium of claim 14, wherein the presentation of the first portion of the generated script by the synthetic character is presented over a background including the at least part of the first image data, and wherein the presentation of the second portion of the generated script by the synthetic character is presented over a background including the at least part of the second image data.

16. The non-transitory computer readable medium of claim 14, wherein the first portion of the generated script is related to a first object at the first section of the construction site, the second portion of the generated script is related to a second object at the second section of the construction site, and the generated visual representation of the synthetic character presenting the generated script includes:
a visual representation of the synthetic character visually indicating a depiction of the first object in the at least part of the first image data while presenting the first portion of the generated script; and
a visual representation of the synthetic character visually indicating a depiction of the second object in the at least part of the second image data while presenting the second portion of the generated script.

17. The non-transitory computer readable medium of claim 14, wherein the first portion of the generated script is related to a construction error at the first section of the construction site, the second portion of the generated script is related to a construction error at the second section of the construction site, and the generated visual representation of the synthetic character presenting the generated script includes:
a visual representation of the synthetic character visually indicating a location in the at least part of the first image data associated with the construction error at the first section of the construction site while presenting the first portion of the generated script; and
a visual representation of the synthetic character visually indicating a location in the at least part of the second image data associated with the construction error at the second section of the construction site while presenting the second portion of the generated script.

18. The non-transitory computer readable medium of claim 14, wherein the generated visual representation of the synthetic character presenting the generated script includes a depiction of the synthetic character walking from the first section of the construction site to the second section of the construction site.

19. A system for generating and presenting scripts related to different sections of construction sites, the system comprising:
at least one processor configured to:
receive first information and second information, the first information is based on an analysis of a first image data captured from a first section of a construction site and the second information is based on an analysis of a second image data captured from a second section of the construction site, the second section of the construction site differs from the first section of the construction site;
generate a script based on the first information and the second information, the generated script includes at least a first portion associated with the first section of the construction site and a second portion associated with the second section of the construction site; and
cause a presentation of the generated script, the presentation of the generated script includes a presentation of the first portion of the generated script in conjunction with a visual presentation of at least part of the first image data and a presentation of the second portion of the generated script in conjunction with a visual presentation of at least part of the second image data.

20. A method for generating and presenting scripts related to different sections of construction sites, the method comprising:
receiving first information and second information, the first information is based on an analysis of a first image data captured from a first section of a construction site and the second information is based on an analysis of a second image data captured from a second section of the construction site, the second section of the construction site differs from the first section of the construction site;
generating a script based on the first information and the second information, the generated script includes at least a first portion associated with the first section of the construction site and a second portion associated with the second section of the construction site; and
causing a presentation of the generated script, the presentation of the generated script includes a presentation of the first portion of the generated script in conjunction with a visual presentation of at least part of the first image data and a presentation of the second portion of the generated script in conjunction with a visual presentation of at least part of the second image data.
